(19) United States
(12) Patent Application Publication
(10) Pub. No.: US 2026/0341195 A1
(43) Pub. Date: Oct. 29, 2026

(54) Light-Emitting Substrate and Manufacturing Method and Driving Method Therefor, and Display Panel

(71) Applicants: BOE MLED Technology Co., Ltd., Beijing (CN); BOE TECHNOLOGY GROUP CO., LTD., Chaoyang District, Beijing (CN); BEIJING BOE TECHNOLOGY DEVELOPMENT CO., LTD., Beijing (CN)

(72) Inventors: Jiawei Zhao, Beijing (CN); Chenchang Chen, Beijing (CN); Qiuhua Meng, Beijing (CN); Yuanda Lu, Beijing (CN); Junjie Ma, Beijing (CN); Zhijun Xiong, Beijing (CN); Yuanhao Sun, Beijing (CN); Qi Fan, Beijing (CN); Zedan Chen, Beijing (CN)

(21) Appl. No.: 19/112,436

(22) PCT Filed: Sep. 15, 2023
(86) PCT No.: PCT/CN2023/119185

§ 371 Date: Mar. 17, 2025

(51) Int. Cl. G09G 3/32; H10H 29/01; H10H 29/03

(52) U.S. Cl. CPC G09G 3/32; H10H 29/012; H10H 29/03; G09G 2320/0233; G09G 2320/0242

(57) ABSTRACT

A light-emitting substrate includes a base substrate and light-emitting units located on the base substrate. The light-emitting units include first light-emitting units, second light-emitting units, third light-emitting units, and compensation light-emitting units. In the color coordinates, a distance between a coordinate point of first color light emitted by one first light-emitting unit and a coordinate point of first color light emitted by another first light-emitting unit is greater than or equal to 0.035, and/or a distance between a coordinate point of second color light emitted by one second light-emitting unit and a coordinate point of second color light emitted by another second light-emitting unit is greater than or equal to 0.023, and/or a distance between a coordinate point of third color light emitted by one third light-emitting unit and a coordinate point of third color light emitted by another third light-emitting unit is greater than or equal to 0.004.

### CROSS-REFERENCE TO RELATED APPLICATION

This application is the United States national phase of International Patent Application No. PCT/CN2023/119185, filed Sep. 15, 2023, the disclosure of which is hereby incorporated by reference in its entirety.

### BACKGROUND OF THE INVENTION

### Field of the Invention

The present disclosure relates to the field of display technologies, and in particular, to a light-emitting substrate and a manufacturing method and a driving method therefor, and a display panel.

### Description of Related Art

The mini light-emitting diode (Mini LED) display panels and micro light-emitting diode (Micro LED) display panels have excellent performance, such as low power consumption, fast response, long lifespan, high color saturation, and high contrast.

With the continuous development of display technologies, Mini LED display panels and Micro LED display panels will be increasingly used in a wide range of applications.

### SUMMARY OF THE INVENTION

In an aspect, a light-emitting substrate is provided. The light-emitting substrate includes a base substrate and a plurality of light-emitting units. The base substrate includes a plurality of pixel unit regions. The plurality of light-emitting units are located on a side of the base substrate. The plurality of light-emitting units include a plurality of first light-emitting units, a plurality of second light-emitting units, a plurality of third light-emitting units, and a plurality of compensation light-emitting units, in which each pixel unit region is provided therein with a first light-emitting unit in the first light-emitting units, a second light-emitting unit in the second light-emitting units, a third light-emitting unit in the third light-emitting units, and at least one compensation light-emitting unit in the compensation light-emitting units. A distance between a coordinate point of first color light emitted by one of the first light-emitting units in color coordinates and a coordinate point of first color light emitted by another of the first light-emitting units in the color coordinates is greater than or equal to 0.035.

In some embodiments, a distance between a coordinate point of second color light emitted by one of the second light-emitting units in the color coordinates and a coordinate point of second color light emitted by another of the second light-emitting units in the color coordinates is greater than or equal to 0.023.

In some embodiments, a distance between a coordinate point of third color light emitted by one of the third light-emitting units in the color coordinates and a coordinate point of third color light emitted by another of the third light-emitting units in the color coordinates is greater than or equal to 0.005.

In some embodiments, a distance between a coordinate point of first color light emitted by one of the first light-emitting units in color coordinates and a coordinate point of first color light emitted by another of the first light-emitting units in the color coordinates is greater than or equal to 0.042.

In some embodiments, a distance between a coordinate point of second color light emitted by one of the second light-emitting units in the color coordinates and a coordinate point of second color light emitted by another of the second light-emitting units in the color coordinates is greater than or equal to 0.026.

In some embodiments, a distance between a coordinate point of third color light emitted by one of the third light-emitting units in the color coordinates and a coordinate point of third color light emitted by another of the third light-emitting units in the color coordinates is greater than or equal to 0.007.

In some embodiments, an area of a first MacAdam ellipse region corresponding to third color light emitted by the third light-emitting unit is less than an area of a second MacAdam ellipse region corresponding to mixed light of the third color light emitted by the third light-emitting unit and compensation light emitted by a compensation light-emitting unit.

In some embodiments, a range value of the first MacAdam ellipse region on a first coordinate axis in the color coordinates is less than a range value of the second MacAdam ellipse region on the first coordinate axis.

In some embodiments, a range value of the first MacAdam ellipse region on a second coordinate axis in the color coordinates is less than a range value of the second MacAdam ellipse region on the second coordinate axis.

In some embodiments, a ratio of a range value of the third color light on a first coordinate axis in the color coordinates to a range value of the first MacAdam ellipse region on the first coordinate axis is M1, and a ratio of a range value of the mixed light of the third color light and the compensation light on the first coordinate axis in the color coordinates to a range value of the second MacAdam ellipse region on the first coordinate axis is N1, M1 being greater than N1.

In some embodiments, a ratio of a range value of the third color light on a second coordinate axis in the color coordinates to a range value of the first MacAdam ellipse region on the second coordinate axis is M2, and a ratio of a range value of the mixed light of the third color light and the compensation light on the second coordinate axis in the color coordinates to a range value of the second MacAdam ellipse region on the second coordinate axis is N2, M2 being greater than N2.

In some embodiments, a pixel unit region in the pixel unit regions is provided therein with one first light-emitting unit, one second light-emitting unit, one third light-emitting unit, and one compensation light-emitting unit. An attenuation rate of an emission luminance of the first light-emitting unit corresponding to a single lighting duration is greater than an attenuation rate of an emission luminance of the second light-emitting unit corresponding to the single lighting duration, and the attenuation rate of the emission luminance of the first light-emitting unit corresponding to the single lighting duration is greater than an attenuation rate of an emission luminance of the third light-emitting unit corresponding to the single lighting duration. The compensation light-emitting unit is located adjacent to the first light-emitting unit.

In some embodiments, a pixel unit region in the pixel unit regions is provided therein with one first light-emitting unit, one second light-emitting unit, one third light-emitting unit, and two compensation light-emitting units. An emission luminance of the first light-emitting unit is less than an emission luminance of the second light-emitting unit, and the emission luminance of the second light-emitting unit is greater than an emission luminance of the third light-emitting unit. One of the two compensation light-emitting units is located adjacent to the first light-emitting unit, and the other of the two compensation light-emitting units is located adjacent to the third light-emitting unit.

In some embodiments, a pixel unit region in the pixel unit regions is provided therein with one first light-emitting unit, one second light-emitting unit, one third light-emitting unit, and three compensation light-emitting units. The three compensation light-emitting units include a first compensation light-emitting unit, a second compensation light-emitting unit, and a third compensation light-emitting unit. Along a direction parallel to the base substrate, the first compensation light-emitting unit is located adjacent to the first light-emitting unit, the second compensation light-emitting unit is located adjacent to the second light-emitting unit, and the third compensation light-emitting unit is located adjacent to the third light-emitting unit.

In some embodiments, a ratio of an emission luminance of the first compensation light-emitting unit to an emission luminance of the first light-emitting unit, a ratio of an emission luminance of the second compensation light-emitting unit to an emission luminance of the second light-emitting unit, and a ratio of an emission luminance of the third compensation light-emitting unit to an emission luminance of the third light-emitting unit are different from each other.

In some embodiments, an attenuation rate of an emission luminance of the first light-emitting unit corresponding to a single lighting duration is greater than an attenuation rate of an emission luminance of the second light-emitting unit corresponding to the single lighting duration; a difference between a ratio of an emission luminance of the first compensation light-emitting unit to an emission luminance of the first light-emitting unit at a first moment and a ratio of an emission luminance of the first compensation light-emitting unit to an emission luminance of the first light-emitting unit at a second moment is a first ratio difference; a difference between a ratio of an emission luminance of the second compensation light-emitting unit to an emission luminance of the second light-emitting unit at the first moment and a ratio of an emission luminance of the second compensation light-emitting unit to an emission luminance of the second light-emitting unit at the second moment is a second ratio difference; and the first ratio difference is greater than the second ratio difference, where the first moment is a moment between a lighting moment and the second moment.

In some embodiments, an attenuation rate of an emission luminance of the second light-emitting unit corresponding to a single lighting duration is greater than an attenuation rate of an emission luminance of the third light-emitting unit corresponding to the single lighting duration; a difference between a ratio of an emission luminance of the second compensation light-emitting unit to an emission luminance of the second light-emitting unit at the first moment and a ratio of an emission luminance of the second compensation light-emitting unit to an emission luminance of the second light-emitting unit at the second moment is a third ratio difference; a difference between a ratio of an emission luminance of the third compensation light-emitting unit to an emission luminance of the third light-emitting unit at the first moment and a ratio of an emission luminance of the third compensation light-emitting unit to an emission luminance of the third light-emitting unit at the second moment is a fourth ratio difference; and the third ratio difference is greater than the fourth ratio difference, where the first moment is a moment between a lighting moment and the second moment.

In some embodiments, in different pixel unit regions, a ratio of an emission luminance of a compensation light-emitting unit to an emission luminance of the first light-emitting unit is substantially the same.

In some embodiments, in different pixel unit regions, a ratio of an emission luminance of a compensation light-emitting unit to an emission luminance of the second light-emitting unit is substantially the same.

In some embodiments, in different pixel unit regions, a ratio of an emission luminance of a compensation light-emitting unit to an emission luminance of the third light-emitting unit is substantially the same.

In some embodiments, a ratio of an emission luminance of a compensation light-emitting unit to an emission luminance of the first light-emitting unit is greater than or equal to 10% and less than or equal to 50%.

In some embodiments, a ratio of an emission luminance of a compensation light-emitting unit to an emission luminance of the second light-emitting unit is greater than or equal to 10% and less than or equal to 50%.

In some embodiments, a ratio of an emission luminance of a compensation light-emitting unit to an emission luminance of the third light-emitting unit is greater than or equal to 10% and less than or equal to 50%.

In some embodiments, a light-emitting area of a compensation light-emitting unit is substantially equal to a light-emitting area of the first light-emitting unit.

In some embodiments, a light-emitting area of a compensation light-emitting unit is substantially equal to a light-emitting area of the second light-emitting unit.

In some embodiments, a light-emitting area of a compensation light-emitting unit is substantially equal to a light-emitting area of the third light-emitting unit.

In some embodiments, a coordinate point of compensation light emitted by the at least one compensation light-emitting unit in the color coordinates is located within a region enclosed by lines connecting a first color coordinate point (0.3275, 0.3577), a second color coordinate point (0.3750, 0.6250), and a third color coordinate point (0.6000, 0.4000).

In some embodiments, a coordinate point of compensation light emitted by a compensation light-emitting unit in the compensation light-emitting units in the color coordinates is located within a region enclosed by lines connecting a first color coordinate point (0.3275, 0.3577), a fourth color coordinate point (0.2800, 0.2500), and a fifth color coordinate point (0.2600, 0.2600).

In some embodiments, a coordinate point of compensation light emitted by a compensation light-emitting unit in the compensation light-emitting units in the color coordinates is located within a region enclosed by lines connecting a first color coordinate point (0.3275, 0.3577), a sixth color coordinate point (0.4500, 0.5500), and a seventh color coordinate point (0.5000, 0.5000).

In another aspect, a manufacturing method for a light-emitting substrate is provided. The manufacturing method for the light-emitting substrate includes forming a base substrate, the base substrate including a plurality of pixel unit regions; and forming a plurality of light-emitting units on a side of the base substrate. The plurality of light-emitting units includes a plurality of first light-emitting units, a plurality of second light-emitting units, a plurality of third light-emitting units, and a plurality of compensation light-emitting units, in which each pixel unit region is provided therein with a first light-emitting unit in the first light-emitting units, a second light-emitting unit in the second light-emitting units, a third light-emitting unit in the third light-emitting units, and at least one compensation light-emitting unit in the compensation light-emitting units. A distance between a coordinate point of first color light emitted by one of the first light-emitting units in color coordinates and a coordinate point of first color light emitted by another of the first light-emitting units in the color coordinates is greater than or equal to 0.035; and/or a distance between a coordinate point of second color light emitted by one of the second light-emitting units in the color coordinates and a coordinate point of second color light emitted by another of the second light-emitting units in the color coordinates is greater than or equal to 0.023; and/or a distance between a coordinate point of third color light emitted by one of the third light-emitting units in the color coordinates and a coordinate point of third color light emitted by another of the third light-emitting units in the color coordinates is greater than or equal to 0.005.

In some embodiments, forming the plurality of light-emitting units on the side of the base substrate includes: forming the plurality of first light-emitting units, the plurality of second light-emitting units, the plurality of third light-emitting units, and the plurality of compensation light-emitting units on different sapphire substrates, respectively; and transferring the plurality of first light-emitting units, the plurality of second light-emitting units, the plurality of third light-emitting units, and the plurality of compensation light-emitting units, independently, directly to the side of the base substrate to form the plurality of light-emitting units.

In yet another aspect, a driving method for a light-emitting substrate is provided. The driving method for the light-emitting substrate includes adjusting a luminance of at least one of the first light-emitting unit, the second light-emitting unit, the third light-emitting unit, and the compensation light-emitting unit separately, by adjusting a driving current or a duty cycle of a driving voltage. A distance between a coordinate point of first color light emitted by one of the first light-emitting units in color coordinates and a coordinate point of first color light emitted by another of the first light-emitting units in the color coordinates is greater than or equal to 0.035.

In some embodiments, a distance between a coordinate point of second color light emitted by one of the second light-emitting units in the color coordinates and a coordinate point of second color light emitted by another of the second light-emitting units in the color coordinates is greater than or equal to 0.023.

In some embodiments, a distance between a coordinate point of third color light emitted by one of the third light-emitting units in the color coordinates and a coordinate point of third color light emitted by another of the third light-emitting units in the color coordinates is greater than or equal to 0.005

In still another aspect, a display panel is provided. The display panel includes the light-emitting substrate according to any one of the above embodiments.

In some embodiments, the display panel includes a display region. A ratio of light-emitting areas of the plurality of compensation light-emitting units to an area of the display region is greater than or equal to 0.1% and less than or equal to 5%.

### BRIEF DESCRIPTION OF THE DRAWINGS

In order to describe technical solutions in the present disclosure more clearly, the accompanying drawings to be used in some embodiments of the present disclosure will be introduced briefly. It is obvious that the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display panel, in accordance with some embodiments;

FIG. 2 is a structural diagram of a light-emitting substrate, in accordance with some embodiments;

FIG. 3 and FIG. 4 are each a cross-sectional view of a light-emitting substrate taken along the line A-A′ in FIG. 2, in accordance with some embodiments;

FIG. 5 and FIG. 6 are each a structural diagram of a light-emitting unit in a light-emitting substrate, in accordance with some embodiments;

FIG. 7 is a structural diagram of pixel circuits and light-emitting units in a light-emitting substrate, in accordance with some embodiments;

FIG. 8 and FIG. 9 are each a structural diagram of light-emitting units in a light-emitting substrate, in accordance with some embodiments;

FIG. 10 and FIG. 11 are each a structural diagram of pixel circuits and light-emitting units in a light-emitting substrate, in accordance with some embodiments;

FIG. 12 is a chromaticity diagram of light emitted by a third light-emitting unit and a compensation light-emitting unit in a light-emitting substrate, in accordance with some embodiments;

FIG. 13 is a graph of luminance ratios of light-emitting units in a light-emitting substrate varying with temperature, in accordance with some embodiments;

FIG. 14 to FIG. 16 are each a chromaticity diagram of light emitted by light-emitting units in a light-emitting substrate, in accordance with some embodiments;

FIG. 17 is a chromaticity diagram of light emitted by a third light-emitting unit and a compensation light-emitting unit in a light-emitting substrate, in accordance with some embodiments;

FIG. 18 is a chromaticity diagram of light emitted by a third light-emitting unit and a compensation light-emitting unit in a light-emitting substrate, in accordance with some embodiments;

FIG. 19 is a flowchart of a manufacturing method for a light-emitting substrate, in accordance with some embodiments; and

FIG. 20 is a flowchart of a manufacturing method for a light-emitting substrate, in accordance with some embodiments.

### DESCRIPTION OF THE INVENTION

The technical solutions in some embodiments of the present disclosure will be described clearly and completely with reference to the accompanying drawings. It is obvious that the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, terms such as “one embodiment,” “some embodiments,” “exemplary embodiments,” “example,” “specific example,” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a plurality of” or “multiple” means two or more unless otherwise specified.

In the description of some embodiments, the terms “coupled” and “connected” and derivatives thereof may be used. For example, the term “connected” may represent a fixed connection, a detachable connection, or a one-piece connection; alternatively, the term “connected” may represent a direct connection or an indirect connection through an intermediate medium. The term “coupled,” for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is, optionally, construed to mean “when” or “in a case where” or “in response to determining” or “in response to detecting,” depending on the context. Similarly, the phrase “if it is determined” or “if [a stated condition or event] is detected” is, optionally, construed to mean “in a case where it is determined” or “in response to determining” or “in a case where [the stated condition or event] is detected” or “in response to detecting [the stated condition or event]”, depending on the context.

The use of “applicable to” or “configured to” herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or value beyond those stated.

The term such as “about,” “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel,” “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

In the process of epitaxial growth of wafers to form light-emitting units, the wafers are easily affected by airflow, temperature and other factors, resulting in differences in the photoelectric properties of light-emitting units from different batches/bins. For Mini LED display panels and Micro LED display panels, it is necessary to detect the photoelectric properties of the light-emitting units through a test current, and then carry out strict screening, grading and grouping on the light-emitting units based on the different photoelectric properties, so as to facilitate the mass transfer of light-emitting units to ensure the display effect of the display panels. In order to ensure the uniformity of the display effect of a display panel, light-emitting units that emit the same color light in the same display panel employ light-emitting units with photoelectric properties at the same grade.

However, the inventors of the present disclosure have found that an operating current of the light-emitting unit using an active driving mode is less than the test current, which results in the photoelectric properties of the light-emitting unit driven by the test current failing to accurately reflect the photoelectric properties of the light-emitting unit actually driven by the operating current in the display panel. When testing multiple light-emitting units emitting light of the same color with approximately the same photoelectric properties, there is a large difference between the actual photoelectric properties driven by the operating current, resulting in an uneven chromaticity between different light-emitting units emitting light of the same color. Moreover, the operating current of the light-emitting unit using the active driving mode is small, resulting in an insufficient luminance of the display panel.

In addition, in a case where each light-emitting unit has a small size, it is more difficult to test the photoelectric properties of the light-emitting unit, which reduces the manufacturing efficiency of a light-emitting substrate. In the case where the size of the light-emitting unit is too small to allow testing of its photoelectric properties, since the light-emitting unit cannot be graded, there may occur a situation where there are multiple grades of a same color for the same light-emitting substrate, resulting in a low light-emitting uniformity of the light-emitting substrate.

In light of this, embodiments of the present disclosure provide a light-emitting substrate and a manufacturing method and a driving method therefor, and a display panel to solve the above problems, each of which is described below.

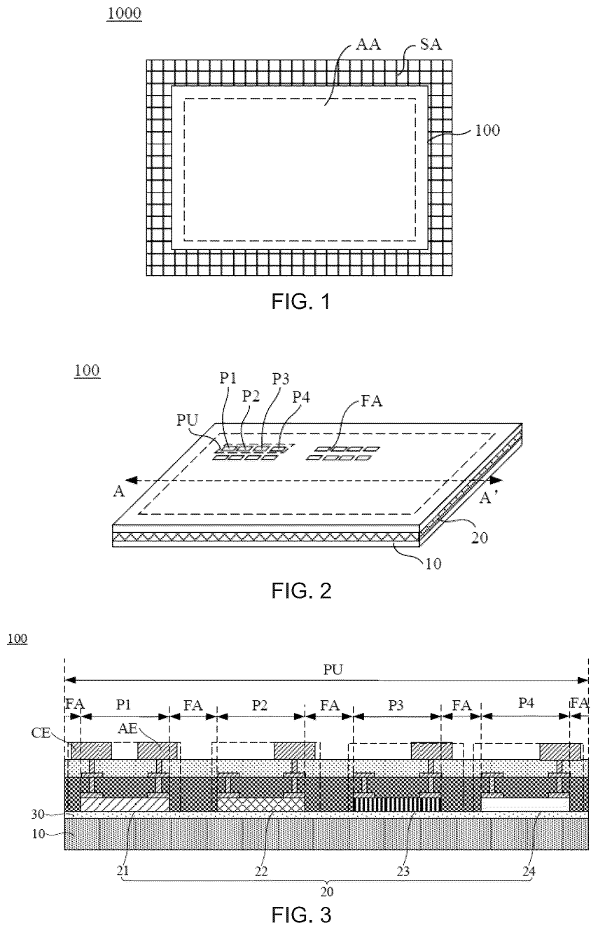

FIG. 1 is a structural diagram of the display panel, in accordance with some embodiments. Referring to FIG. 1, some embodiments of the present disclosure provide a display panel 1000. The display panel 1000 can be used to display a static image or a dynamic picture. For example, the display panel 1000 may be a Mini LED display panel or a Micro LED display panel.

For example, the display panel 1000 may be contained within a terminal device, where the terminal device may be a small-to-medium-sized display device, such as a tablet computer, a smartphone, a head-mounted display, a car navigation unit, a camera, an in-vehicle center information display, a watch-type display device or any of the other wearable devices, a personal digital assistant, a portable multimedia player, or a game console; alternatively, the terminal device may be a medium-to-large-sized electronic device, such as a television, an outdoor billboard, a monitor, a home appliance containing a display screen, a personal computer, or a laptop. The electronic device as described above may represent mere examples of the application of the display panel 1000, and thus those skilled in the art may recognize that the display panel 1000 may also be applied to other electronic devices without departing from the spirit and scope of the present disclosure.

As shown in FIG. 1, the display panel 1000 includes a display region AA for displaying images and a non-display region SA for not displaying an image. The non-display region SA is located on at least one side of the display region AA. For example, the non-display region SA may be closed to surround the display region AA or may be located on the outside of the display region AA in at least one direction.

For example, in a plan view, a shape of the display panel 1000 above described may include a rectangle, a circle, an ellipse, a rhombus, a trapezoid, a square, or any of the other shapes as desired for the display.

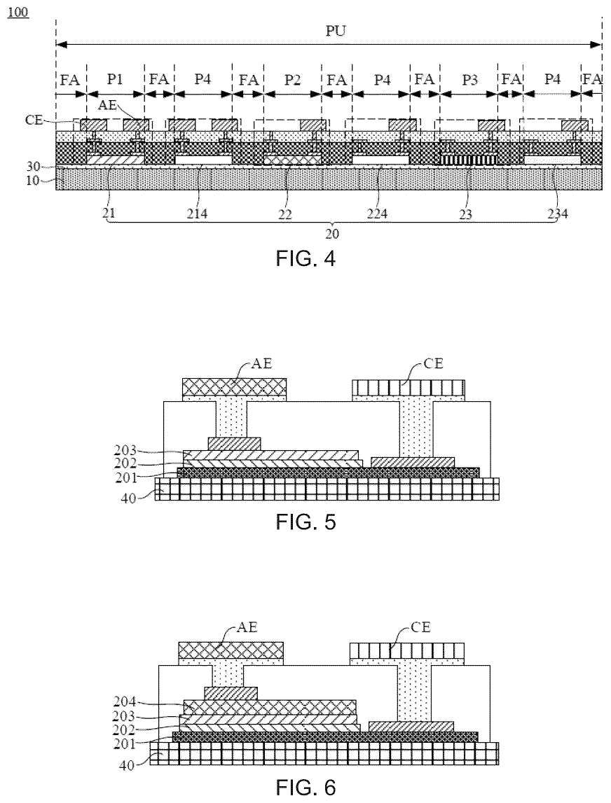

FIG. 2 is a structural diagram of the light-emitting substrate, in accordance with some embodiments. FIG. 3 and FIG. 4 are each a cross-sectional view of the light-emitting substrate taken along the line A-A′ in FIG. 2, in accordance with some embodiments.

Referring to FIG. 2 and FIG. 3, some embodiments of the present disclosure provide a light-emitting substrate 100. The light-emitting substrate 100 is a display component capable of emitting display light, and the light-emitting substrate 100 can emit monochromatic light (light of a single color) or colored light. The light-emitting substrate 100 may be applied in the display panel 1000 above described. For example, the light-emitting substrate 100 may be a Mini LED light-emitting substrate or a Micro LED light-emitting substrate.

In some embodiments, as shown in FIG. 2 and FIG. 3, the light-emitting substrate 100 may include a base substrate 10 and a plurality of light-emitting units 20. The plurality of light-emitting units 20 are located on a side of the base substrate 10, and the plurality of light-emitting units 20 may include a plurality of first light-emitting units 21, a plurality of second light-emitting units 22, a plurality of third light-emitting units 23, and a plurality of compensation light-emitting units 24, in which a first light-emitting unit 21, a second light-emitting unit 22, a third light-emitting unit 23, and at least one compensation light-emitting unit 24 correspond to a pixel unit region PU to be described below. The number of the compensation light-emitting unit(s) 24 corresponding the pixel unit region PU may be one or more.

Compensation light-emitting unit(s) 24 may be disposed adjacent to at least one of the first light-emitting unit 21, the second light-emitting unit 22, and the third light-emitting unit 23. It can be understood that a compensation light-emitting unit 24 may be located adjacent to the first light-emitting unit 21; and/or a compensation light-emitting unit 24 may be located adjacent to the second light-emitting unit 22; and/or a compensation light-emitting unit 24 may be located adjacent to the third light-emitting unit 23. The compensation light-emitting unit 24 can emit compensation light, which can increase an emission luminance of the light-emitting substrate 100.

An emission luminance LR of the first light-emitting unit 21, an emission luminance LG of the second light-emitting unit 22, and an emission luminance LB of the third light-emitting unit 23 can be obtained by individually lighting the first light-emitting unit 21, the second light-emitting unit 22, and the third light-emitting unit 23. An emission luminance of the compensation light-emitting unit 24 can be determined according to the demand for an emission luminance of different colored light in the light-emitting substrate 100. A luminance compensation amount of the compensation light-emitting unit 24 to the first light-emitting unit 21 is Lw1, and Lw1=LR*R1, where R1 is a luminance compensation ratio of the compensation light-emitting unit 24 to the first light-emitting unit 21. A luminance compensation amount of the compensation light-emitting unit 24 to the second light-emitting unit 22 is Lw2, and Lw2=LG*R2, where R2 is a luminance compensation ratio of the compensation light-emitting unit 24 to the second light-emitting unit 22. A luminance compensation amount of the compensation light-emitting unit 24 to the third light-emitting unit 23 is Lw3, and Lw3=LB*R3, where R3 is a luminance compensation ratio of the compensation light-emitting unit 24 to the third light-emitting unit 23. Here, R1, R2, and R³ each take a value less than or equal to 1, and R1, R2, and R3 may be the same or different.

The following are detailed descriptions of the base substrate 10 and the plurality of light-emitting units 20 in the light-emitting substrate 100.

As shown in FIG. 3 and FIG. 4, the base substrate 10 may include a plurality of pixel unit regions PU arranged with repetition. Each pixel unit region PU may include multiple sub-pixel regions and a non-light-emitting region FA located around each sub-pixel region. For example, each pixel unit region PU may include a first sub-pixel region P1, a second sub-pixel region P2, a third sub-pixel region P3, and at least one fourth sub-pixel region P4. The number of the fourth sub-pixel region(s) P4 in each pixel unit region PU may be one or more. A compensation light-emitting unit 24 may be located in a fourth sub-pixel region P4, and in each pixel unit region PU, the number of the compensation light-emitting unit(s) 24 may be equal to the number of the fourth sub-pixel region(s) P4.

In some examples, as shown in FIG. 3, each pixel unit region PU may include one first light-emitting unit 21, one second light-emitting unit 22, one third light-emitting unit 23, and one compensation light-emitting unit 24. For example, the first light-emitting unit 21 may be located in a first sub-pixel region P1, the second light-emitting unit 22 may be located in a second sub-pixel region P2, the third light-emitting unit 23 may be located in a third sub-pixel region P3, and the compensation light-emitting unit 24 may be located in a fourth sub-pixel region P4.

Here, the non-light-emitting region FA may be located between the first sub-pixel region P1 and the second sub-pixel region P2, between the second sub-pixel region P2 and the third sub-pixel region P3, and between the third sub-pixel region P3 and the fourth sub-pixel region P4.

In some examples, each pixel unit region PU may include one first light-emitting unit 21, one second light-emitting unit 22, one third light-emitting unit 23, and two compensation light-emitting units 24. For example, the first light-emitting unit 21 may be located in a first sub-pixel region P1, the second light-emitting unit 22 may be located in a second sub-pixel region P2, the third light-emitting unit 23 may be located in a third sub-pixel region P3, and the two compensation light-emitting units 24 may be located in two fourth sub-pixel regions P4.

In this case, the non-light-emitting region FA may further be located between the first sub-pixel region P1 and one fourth sub-pixel region P4, and between the third sub-pixel region P3 and another fourth sub-pixel region P4.

In some examples, as shown in FIG. 4, each pixel unit region PU may include one first light-emitting unit 21, one second light-emitting unit 22, one third light-emitting unit 23, and three compensation light-emitting units 24. For example, the first light-emitting unit 21 may be located in a first sub-pixel region P1, the second light-emitting unit 22 may be located in a second sub-pixel region P2, the third light-emitting unit 23 may be located in a third sub-pixel region P3, and the three compensation light-emitting units 24 may be located in three fourth sub-pixel regions P4.

In this case, the non-light-emitting region FA may further be located between the first sub-pixel region P1 and one fourth sub-pixel region P4, between the second sub-pixel region P2 and another fourth sub-pixel region P4, and between the third sub-pixel region P3 and yet another fourth sub-pixel region P4.

In some examples, the base substrate 10 may be a flexible base substrate. For example, a material of the flexible base substrate may include an organic material. For example, the material of the flexible base substrate may include any one of polyimide (PI), polycarbonate (PC), or polyvinyl chloride (PVC).

In some other examples, the base substrate 10 may be a rigid base substrate.

For example, a material of the rigid base substrate may include glass or polymethyl methacrylate (PMMA).

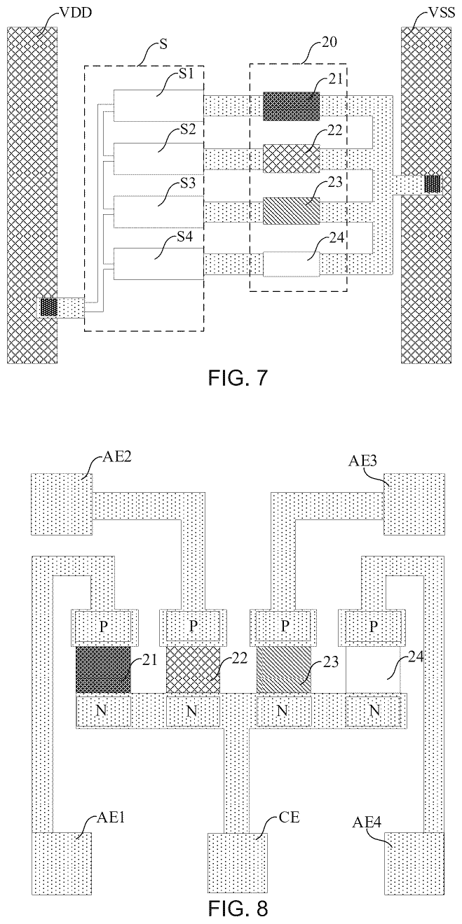

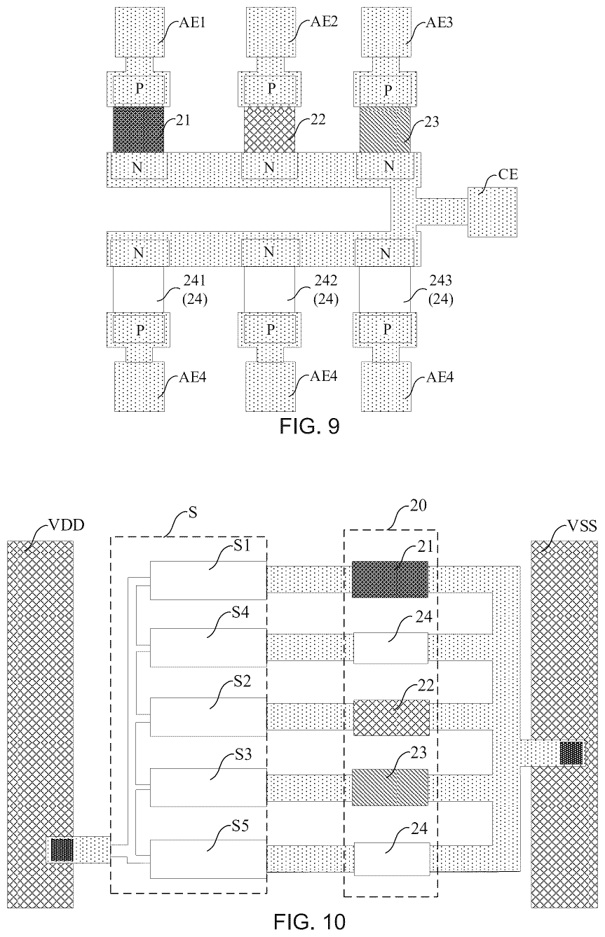

FIG. 5 and FIG. 6 are each a structural diagram of the light-emitting unit in the light-emitting substrate, in accordance with some embodiments. FIG. 7 is a structural diagram of pixel circuits and light-emitting units in the light-emitting substrate, in accordance with some embodiments. FIG. 8 and FIG. 9 are each a structural diagram of light-emitting units in the light-emitting substrate, in accordance with some embodiments.

As shown in FIG. 3 to FIG. 9, the plurality of light-emitting units 20 may be located on a side of an insulating layer 30 away from the base substrate 10. Each light-emitting unit 20 may include a first electrode AE (e.g., an anode) and a second electrode CE (e.g., a cathode). For example, the light-emitting unit 20 may include a Mini LED or a Micro LED.

As shown in FIG. 5 and FIG. 6, the light-emitting unit 20 may further include a first semiconductor layer 201, a light-generating layer 202, and a second semiconductor layer 203 that are stacked in sequence. For example, the first semiconductor layer 201 may be coupled to the second electrode CE, and the second semiconductor layer 203 may be coupled to the first electrode AE.

In a case where different voltages are applied to the first electrode AE and the second electrode CE to form an electric field therebetween, a PN junction having a potential barrier can be formed between the first semiconductor layer 201 and the second semiconductor layer 203, so carriers in the first semiconductor layer 201 and carriers in the second semiconductor layer 203 will enter the light-generating layer 202 and undergo a recombination, whereby excess energy is released in the form of light, thereby directly converting electrical energy into light energy to enable the light-emitting unit 20 to emit light.

In some examples, the first semiconductor layer 201 may be one of an N-type semiconductor and a P-type semiconductor, and the second semiconductor layer 203 may be the other of the N-type semiconductor and the P-type semiconductor. For example, the first semiconductor layer 201 may be an N-type semiconductor and the second semiconductor layer 203 may be a P-type semiconductor. As another example, the first semiconductor layer 201 may be a P-type semiconductor and the second semiconductor layer 203 may be an N-type semiconductor.

For example, a material of each of the first semiconductor layer 201 and the second semiconductor layer 203 may include gallium nitride (GaN).

For example, the light-generating layer 202 may be a multiple quantum well (MQW) layer.

In some examples, as shown in FIG. 6, the light-emitting unit 20 may further include a current extension layer 204. The current extension layer 204 may be located between the second semiconductor layer 203 and the first electrode AE. For example, a material of the current extension layer 204 may include a material with good electrical conductivity such as indium tin oxide (ITO). The current extension layer 204 having good electrical conductivity can reduce the resistance of the light-emitting unit 20, which is favorable to the transmission of holes, and thus can improve the electrical performance of the light-emitting unit 20.

It will be noted that the structure of the light-emitting unit 20 in any embodiment herein may be the same as the structure of the light-emitting unit 20 shown in FIG. 5 or FIG. 6. However, some embodiments of the present disclosure are not limited thereto. That is, FIG. 5 and FIG. 6 only illustrate the light-emitting unit 20 being a Mini LED with a flip-chip structure, and in some other embodiments, the light-emitting unit 20 may be a light-emitting unit with a top-emitting structure or a light-emitting unit with a vertical structure.

In some examples, in each pixel unit region PU, multiple light-emitting units 20 may share one first electrode AE, and the multiple light-emitting units 20 may have second electrodes CE independent of each other. For example, in each pixel unit region PU, a first electrode of a first light-emitting unit 21, a first electrode of a second light-emitting unit 22, a first electrode of a third light-emitting unit 23, and a first electrode of a compensation light-emitting unit 24 may be the same one, and a second electrode of the first light-emitting unit 21, a second electrode of the second light-emitting unit 22, a second electrode of the third light-emitting unit 23, and a second electrode of the compensation light-emitting unit 24 may be independent of each other.

In some examples, as shown in FIG. 7, FIG. 8 and FIG. 9, in each pixel unit region PU, multiple light-emitting units 20 may have first electrodes AE independent of each other, and the multiple light-emitting units 20 may share one second electrode CE. For example, as shown in FIG. 8, in each pixel unit region PU, a first electrode AE1 of a first light-emitting unit 21, a first electrode AE2 of a second light-emitting unit 22, a first electrode AE3 of a third light-emitting unit 23, and a first electrode AE4 of a compensation light-emitting unit 24 may be independent of each other, and a second electrode CE of the first light-emitting unit 21, a second electrode CE of the second light-emitting unit 22, a second electrode CE of the third light-emitting unit 23, and a second electrode CE of the compensation light-emitting unit 24 may be the same one. As another example, as shown in FIG. 9, in each pixel unit region PU, a first electrode AE1 of a first light-emitting unit 21, a first electrode AE2 of a second light-emitting unit 22, a first electrode AE3 of a third light-emitting unit 23, and first electrodes AE4 of three compensation light-emitting units 24 may be independent of each other, and a second electrode CE of the first light-emitting unit 21, a second electrode CE of the second light-emitting unit 22, a second electrode CE of the third light-emitting unit 23, and second electrodes CE of the three compensation light-emitting units 24 may be the same one.

In some examples, the plurality of light-emitting units 20 may have first electrodes AE independent of each other, and the plurality of light-emitting units 20 may also have second electrodes CE independent of each other. For example, first electrodes of the plurality of first light-emitting units 21, first electrodes of the plurality of second light-emitting units 22, first electrodes of the plurality of third light-emitting units 23, and first electrodes of the plurality of compensation light-emitting units 24 may be independent of each other, and second electrodes of the plurality of first light-emitting units 21, second electrodes of the plurality of second light-emitting units 22, second electrodes of the plurality of third light-emitting units 23, and second electrodes of the plurality of compensation light-emitting units 24 may also be independent of each other.

The first light-emitting unit 21, the second light-emitting unit 22, the third light-emitting unit 23, and the compensation light-emitting unit 24 may each emit light of a different color. For example, the first light-emitting unit 21 may be configured to emit first color light, the second light-emitting unit 22 may be configured to emit second color light, the third light-emitting unit 23 may be configured to emit third color light, and the compensation light-emitting unit 24 may be configured to emit compensation light.

For example, the first color light may be red light, the second color light may be green light, the third color light may be blue light, and the compensation light may be white compensation light and/or yellow compensation light.

For example, a material of a light-emitting body of the light-emitting unit 20 may include an indium gallium nitride (InGaN) material system, an aluminum indium gallium nitride (AlInGaN) material system, or an aluminum indium gallium phosphide (AlInGaP) material system. For example, a material of a light-emitting body of the compensation light-emitting unit 24 may include an AlInGaN material system or an AlInGaP material system.

Here, the stability of the InGaN material system and the AlInGaP material system is relatively high, so the chromaticity uniformity of light emitted by the light-emitting unit 20 made of the InGaN material system or the AlInGaP material system is relatively good.

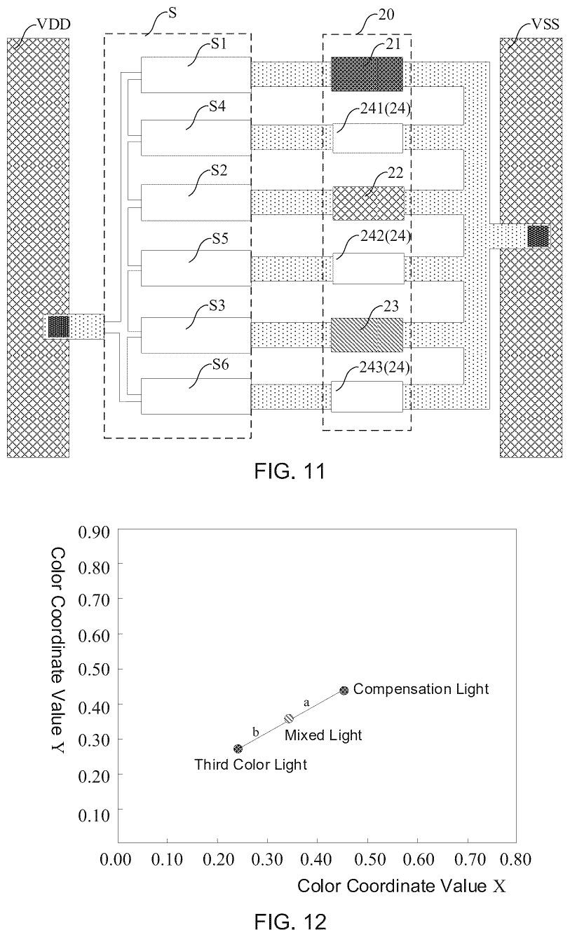

FIG. 10 and FIG. 11 are each a structural diagram of pixel circuits and light-emitting units in the light-emitting substrate, in accordance with some embodiments.

As shown in FIG. 3, FIG. 4, FIG. 7, FIG. 10, and FIG. 11, the light-emitting substrate 100 may include a plurality of pixel circuits S, a first power supply line VDD, and a second power supply line VSS that are located between the base substrate 10 and the plurality of light-emitting units 20.

The plurality of light-emitting units 20 may be coupled with the plurality of pixel circuits S in correspondence. For example, the plurality of light-emitting units 20 may be coupled to the plurality of pixel circuits S in one-to-one correspondence. As another example, at least two of the light-emitting units 20 may be coupled to one of the pixel circuits S.

A first terminal of a pixel circuit S is coupled to the first power supply line VDD, and a second terminal of the pixel circuit S is coupled to a first terminal of a light-emitting unit 20. The second terminal of the light-emitting unit 20 is coupled to the second power supply line VSS. For example, the plurality of pixel circuits S may include first pixel circuits S1, second pixel circuits S2, third pixel circuits S3, and fourth pixel circuits S4. A first terminal of a first pixel circuit S1 is coupled to the first power supply line VDD, and a second terminal of the first pixel circuit S1 is coupled to a first terminal of a first light-emitting unit 21. A second terminal of the first light-emitting unit 21 is coupled to the second power supply line VSS. The first pixel circuit S1 may transmit a first power supply signal on the first power supply line VDD to the first light-emitting unit 21, and the first light-emitting unit 21 can operate driven by the first power supply signal and a second power supply signal on the second power supply line VSS. Accordingly, a connection manner of a second pixel circuit S2 with a second light-emitting unit 22, a connection manner of a third pixel circuit S3 with a third light-emitting unit 23, and a connection manner of a fourth pixel circuit S4 with a compensation light-emitting unit 24 can be referred to as a connection manner of the first pixel circuit S1 with the first light-emitting unit 21, which will not be described herein.

A structure of the pixel circuit S may be varied and may be selected and set according to the actual need. For example, the pixel circuit S may include at least two transistors and at least one capacitor. For example, the pixel circuit S may have a “2T1C,” “6T1C,” “7T1C,” “6T2C,” or “7T2C” structure, where “T” denotes a thin film transistor, and the number in front of “T” denotes the number of thin film transistors; and “C” denotes a storage capacitor, and the number in front of “C” indicates the number of storage capacitors. For example, a thin film transistor in the pixel circuit S may be a thin film transistor containing polycrystalline silicon or a thin film transistor containing an oxide semiconductor.

The light-emitting substrate 100 may further include an insulating layer 30. The insulating layer 30 may be located between the plurality of light-emitting units 20 and the base substrate 10. The insulating layer 30 may have a planarized surface, facilitating the formation of the plurality of light-emitting units 20 on the insulating layer 30. The insulating layer 30 may be formed from an organic layer. For example, the insulating layer 30 may be made of an acrylic resin, an epoxy resin, an imide resin, or an ester resin. The insulating layer 30 may have through holes, and the through holes may expose the pixel circuits S to facilitate an electrical connection of the pixel circuits S to electrodes of the light-emitting units 20.

FIG. 12 is a chromaticity diagram of light emitted by the third light-emitting unit and the compensation light-emitting unit in the light-emitting substrate, in accordance with some embodiments.

In some embodiments, as shown in FIG. 3, FIG. 4, and FIG. 7 to FIG. 11, each pixel unit region PU may be provided therein with a first light-emitting unit 21, a second light-emitting unit 22, a third light-emitting unit 23, and at least one compensation light-emitting unit 24. It can be understood that each pixel unit region may include a first light-emitting unit 21, a second light-emitting unit 22, a third light-emitting unit 23, and a compensation light-emitting unit 24; alternatively, each pixel unit region may include a first light-emitting unit 21, a second light-emitting unit 22, a third light-emitting unit 23, and multiple compensation light-emitting units 24. In each pixel unit region, the number of at least one of the first light-emitting unit 21, the second light-emitting unit 22 and the third light-emitting unit 23 may be one or more, which is not limited here.

According to the principle of light mixing, a plurality of rays of sub-light can form mixed light, and a luminance of the mixed light is the sum of luminances of the plurality of rays of sub-light. Moreover, a distance from a color coordinate point of the mixed light to a color coordinate point of each ray of sub-light has a negatively correlated linear relationship with a luminance of each ray of sub-light. For example, as shown in FIG. 12, when compensation light and third color light are mixed, there are a distance a from a color coordinate point of the mixed light to a color coordinate point of the compensation light, and a distance b from the color coordinate point of the mixed light to a color coordinate point of the third color light. A ratio of the distance a to the distance b is inversely proportional to a ratio of a luminance L1 of the compensation light to a luminance L2 of the third color light. That is, a:b=L2:L1.

The compensation light emitted by the compensation light-emitting unit 24 may be white compensation light or yellow compensation light. The compensation light emitted by the compensation light-emitting unit 24 can be mixed with at least one of the first color light, the second color light and the third color light. The range of the luminance and chromaticity of the compensation light emitted by the compensation light-emitting unit 24 can be adjusted as needed to adjust the range of the luminance and chromaticity of light of each color after mixing, thereby increasing the emission luminance of the light-emitting substrate 100 and improving the chromaticity uniformity of the display light emitted by the light-emitting substrate 100. On the basis of improving the uniformity of the luminance and chromaticity of the light-emitting substrate 100, an acceptable chromaticity range of multiple light-emitting units 20 of the same color in the same light-emitting substrate 100 may be broadened, and the number of grades of the light-emitting units 20 of the same color divided according to the chromaticity may be reduced.

In some other embodiments, when the light-emitting substrate 100 mainly displays light of one color, a luminance of the light mainly displayed will be compensated by auxiliary displaying relatively weaker light of other colors (for example, when the light-emitting substrate 100 mainly displays blue light, a luminance of the blue light will be compensated by auxiliary displaying relatively weaker red light and green light). This method for compensating luminance has a small amount of compensation for the emission luminance of the light-emitting substrate 100 and will also significantly reduce a color gamut coverage area of the light-emitting substrate 100. Furthermore, since a chromaticity range of light of each color emitted by the light-emitting substrate 100 is relatively large, the chromaticity range of light of each color after light mixing is larger, resulting in poor chromaticity uniformity of the display light emitted by the light-emitting substrate 100.

In the embodiments of the present disclosure, the compensation light-emitting unit 24 capable of emitting white compensation light or yellow compensation light is used. The range of the luminance and chromaticity of the white compensation light or yellow compensation light emitted by the compensation light-emitting unit 24 can be adjusted as needed, to enable the mixed light to have a high luminance and a small chromaticity range, thereby greatly increasing the emission luminance of the light-emitting substrate 100 and improving the chromaticity uniformity of the display light emitted by the light-emitting substrate 100. Furthermore, the white compensation light or the yellow compensation light emitted by the compensation light-emitting unit 24 have little influence on the color gamut coverage area of the light-emitting substrate 100, thereby ensuring that the color gamut coverage area of the light-emitting substrate 100 is relatively large.

The color gamut coverage area parameters of light-emitting substrates using different luminance compensation schemes are detailed in Table 1.

TABLE 1

| Color Gamut | | | |
|---|---|---|---|
| Standard | Scheme 1 | Scheme 2 | Scheme 3 |
| BT2020 | 56.7% | 76.9% | 79.2% |
| DCI-P3 | 74.0% | 93.4% | 94.8% |

In Table 1, “Scheme 1” indicates a scheme of using the white compensation light for luminance compensation, “Scheme 2” indicates a scheme of using the first light-emitting unit 21 and the second light-emitting unit 22 for luminance compensation, and “Scheme 3” indicates a scheme of using the yellow compensation light for luminance compensation. Based on the data in Table 1, it can be seen that compared with Scheme 1 and Scheme 2, the color gamut coverage area of the light-emitting substrate using the yellow compensation light for luminance compensation in Scheme 3 is larger.

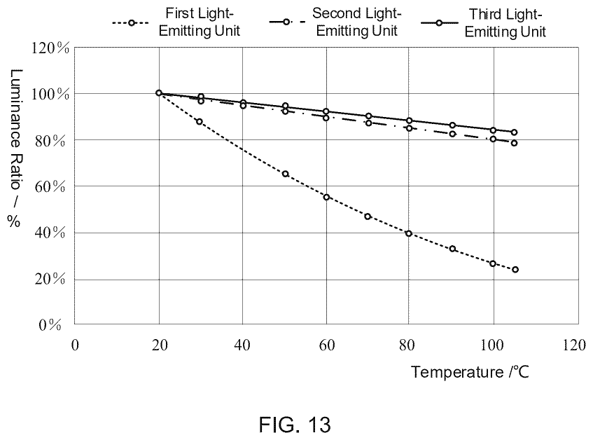

FIG. 13 is a graph showing the relationship between a luminance ratio of a plurality of light-emitting units in the light-emitting substrate and temperature, in accordance with some embodiments. Here, since a temperature of a light-emitting unit has a positive correlation with a single lighting duration of the light-emitting unit, the relationship between the luminance ratio of the light-emitting unit and the single lighting duration of the light-emitting unit can also refer to FIG. 13.

In some examples, as shown in FIG. 3, FIG. 7 and FIG. 8, a pixel unit region PU may be provided therein with one first light-emitting unit 21, one second light-emitting unit 22, one third light-emitting unit 23, and one compensation light-emitting unit 24.

For example, as shown in FIG. 13, an attenuation rate of an emission luminance of the first light-emitting unit 21 corresponding to a single lighting duration is greater than an attenuation rate of an emission luminance of the second light-emitting unit 22 corresponding to the single lighting duration, and the attenuation rate of the emission luminance of the first light-emitting unit 21 corresponding to the single lighting duration is greater than an attenuation rate of an emission luminance of the third light-emitting unit 23 corresponding to the single lighting duration. The compensation light-emitting unit 24 is located adjacent to the first light-emitting unit 21.

For example, the luminance of the compensation light of the compensation light-emitting unit 24 can be adjusted in real-time according to the attenuation rate of the emission luminance of the first light-emitting unit 21 corresponding to the single lighting duration shown in FIG. 13, so as to compensate the emission luminance of the first light-emitting unit 21 in time.

As another example, the compensation light-emitting unit 24 may always keep a compensation amount for the first light-emitting unit 21 greater than a compensation amount for the second light-emitting unit 22, and keep the compensation amount for the first light-emitting unit 21 greater than a compensation amount for the third light-emitting unit 22. In this way, although an intensity of the first color light of the light-emitting substrate will be slightly greater in a case where the attenuation rate of the first light-emitting unit 21 is not much different from that of the second light-emitting unit 22 (or the third light-emitting unit 23), during the entire light-emitting process, the light-emitting substrate with the compensation light-emitting unit compared to a light-emitting substrate without a compensation light-emitting unit can still have an overall display effect improvement.

In this way, the compensation light emitted by the compensation light-emitting unit 24 and the first color light emitted by the first light-emitting unit 21 can be mixed, and the luminance of the compensation light can compensate for the luminance of the first color light, thereby reducing a difference between the luminance attenuation rate of the first color light and the luminance attenuation rate of the second color light, and reducing a difference between the luminance attenuation rate of the first color light and the luminance attenuation rate of the third color light, thereby improving the color deviation problem caused by the fast luminance attenuation of the first color light and ensuring the display effect of the light-emitting substrate 100.

In some examples, as shown in FIG. 10, a pixel unit region may be provided therein with one first light-emitting unit 21, one second light-emitting unit 22, one third light-emitting unit 23, and two compensation light-emitting units 24.

For example, an emission luminance of the first light-emitting unit 21 may be less than an emission luminance of the second light-emitting unit 22, and the emission luminance of the second light-emitting unit 22 may be greater than an emission luminance of the third light-emitting unit 23. One compensation light-emitting unit may be located adjacent to the first light-emitting unit 21, and the other compensation light-emitting unit 24 may be located adjacent to the third light-emitting unit 23. It can be understood that each of the two compensation light-emitting units 24 can emit white compensation light or yellow compensation light.

In this way, compensation light emitted by one compensation light-emitting unit 24 can be mixed with the first color light emitted by the first light-emitting unit 21, which may relatively compensate for the luminance of the first color light, and may reduce the difference between the luminance of the first color light and the luminance of the second color light; and compensation light emitted by the other compensation light-emitting unit 24 can be mixed with the third color light emitted by the third light-emitting unit 23, which may relatively compensate for the luminance of the third color light, and may reduce the difference between the luminance of the third color light and the luminance of the second color light, thereby ensuring the display effect of the light-emitting substrate 100.

In some examples, as shown in FIG. 4, FIG. 9 and FIG. 11, a pixel unit region PU may be provided therein with one first light-emitting unit 21, one second light-emitting unit 22, one third light-emitting unit 23, and three compensation light-emitting units 24.

The three compensation light-emitting units 24 may include a first compensation light-emitting unit 241, a second compensation light-emitting unit 242, and a third compensation light-emitting unit 243. It can be understood that each of the three compensation light-emitting units 24 can emit white compensation light or yellow compensation light.

Along a direction parallel to the base substrate 10, the first compensation light-emitting unit 241 may be located adjacent to the first light-emitting unit 21, the second compensation light-emitting unit 242 may be located adjacent to the second light-emitting unit 22, and the third compensation light-emitting unit 243 may be located adjacent to the third light-emitting unit 23.

In this way, compensation light emitted by the first compensation light-emitting unit 241 can be mixed with the first color light emitted by the first light-emitting unit 21, which can relatively compensate for the luminance of the first color light; compensation light emitted by the second compensation light-emitting unit 242 can be mixed with the second color light emitted by the second light-emitting unit 22, which can relatively compensate for the luminance of the second color light; and compensation light emitted by the third compensation light-emitting unit 243 can be mixed with the third color light emitted by the third light-emitting unit 23, which can relatively compensate for the luminance of the third color light, thereby increasing the emission luminance of the light-emitting substrate 100.

For example, a ratio of an emission luminance of the first compensation light-emitting unit 241 to an emission luminance of the first light-emitting unit 21, a ratio of an emission luminance of the second compensation light-emitting unit 242 to an emission luminance of the second light-emitting unit 22, and a ratio of an emission luminance of the third compensation light-emitting unit 243 to an emission luminance of the third light-emitting unit 23 are different from each other.

For example, the ratio of the emission luminance of the first compensation light-emitting unit 241 to the emission luminance of the first light-emitting unit 21 may be 30%, the ratio of the emission luminance of the second compensation light-emitting unit 242 to the emission luminance of the second light-emitting unit 22 may be 10%, and the ratio of the emission luminance of the third compensation light-emitting unit 243 to the emission luminance of the third light-emitting unit 23 may be 20%.

In this way, the emission luminance of the first light-emitting unit 21 can be compensated by the first compensation light-emitting unit 241, the emission luminance of the second light-emitting unit 22 can be compensated by the second compensation light-emitting unit 242, and the emission luminance of the third light-emitting unit 23 can be compensated by the third compensation light-emitting unit 243. As a result, the number of grades of the light-emitting units 20 divided according to the luminance may be reduced as much as possible, thereby improving the utilization rate of the light-emitting units 20; and the luminance uniformity of the plurality of light-emitting units 20 may be improved.

For example, as shown in FIG. 13, an attenuation rate of an emission luminance of the first light-emitting unit 21 corresponding to a single lighting duration is greater than an attenuation rate of an emission luminance of the second light-emitting unit 22 corresponding to the single lighting duration. A difference between a ratio of an emission luminance of the first compensation light-emitting unit 241 to an emission luminance of the first light-emitting unit 21 at a first moment and a ratio of an emission luminance of the first compensation light-emitting unit 241 to an emission luminance of the first light-emitting unit 21 at a second moment is a first ratio difference. A difference between a ratio of an emission luminance of the second compensation light-emitting unit 242 to an emission luminance of the second light-emitting unit 22 at the first moment and a ratio of an emission luminance of the second compensation light-emitting unit 242 to an emission luminance of the second light-emitting unit 22 at the second moment is a second ratio difference. The first ratio difference is greater than the second ratio difference. Here, the first moment is a moment between a lighting moment and the second moment.

It can be understood that within the same duration, since the emission luminance of the first light-emitting unit 21 is attenuated to a greater extent than the emission luminance of the second light-emitting unit 22, the emission compensation ratio of the first compensation light-emitting unit 241 is greater than the emission compensation ratio of the second compensation light-emitting unit 242.

In this way, the compensation amount of the emission luminance of the first compensation light-emitting unit 241 for the first color may be greater than the compensation amount of the emission luminance of the second compensation light-emitting unit 242 for the second color, which may relatively increase the luminance of the first color light, thereby reducing the difference between the luminance attenuation rate of the first color light and the luminance attenuation rate of the second color light, and alleviating the color deviation problem caused by the fast luminance attenuation of the first color light, so as to ensure the display effect of the light-emitting substrate 100.

For example, as shown in FIG. 13, an attenuation rate of an emission luminance of the second light-emitting unit 22 corresponding to a single lighting duration is greater than an attenuation rate of an emission luminance of the third light-emitting unit 23 corresponding to the single lighting duration. A difference between a ratio of an emission luminance of the second compensation light-emitting unit 242 to an emission luminance of the second light-emitting unit 22 at the first moment and a ratio of an emission luminance of the second compensation light-emitting unit 242 to an emission luminance of the second light-emitting unit 22 at the second moment is a third ratio difference. A difference between a ratio of an emission luminance of the third compensation light-emitting unit 243 to an emission luminance of the third light-emitting unit 23 at the first moment and a ratio of an emission luminance of the third compensation light-emitting unit 243 to an emission luminance of the third light-emitting unit 23 at the second moment is a fourth ratio difference. The third ratio difference is greater than the fourth ratio difference.

Here, the first moment is a moment between a lighting moment and the second moment.

It can be understood that within the same duration, since the emission luminance of the second light-emitting unit 22 is attenuated to a greater extent than the emission luminance of the third light-emitting unit 23, the emission compensation ratio of the second compensation light-emitting unit 242 is greater than the emission compensation ratio of the third compensation light-emitting unit 243.

In this way, the compensation amount of the emission luminance of the second compensation light-emitting unit 242 for the second color may be greater than the compensation amount of the emission luminance of the third compensation light-emitting unit 243 for the third color, which may relatively improve the luminance of the second color light, thereby reducing the difference between the luminance attenuation rate of the second color light and the luminance attenuation rate of the third color light, and alleviating the color deviation problem caused by the fast luminance attenuation of the second color light, so as to ensure the display effect of the light-emitting substrate 100.

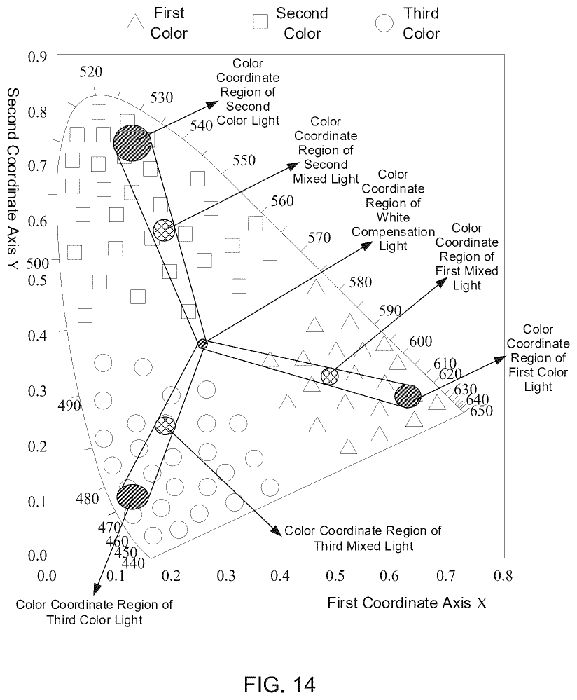

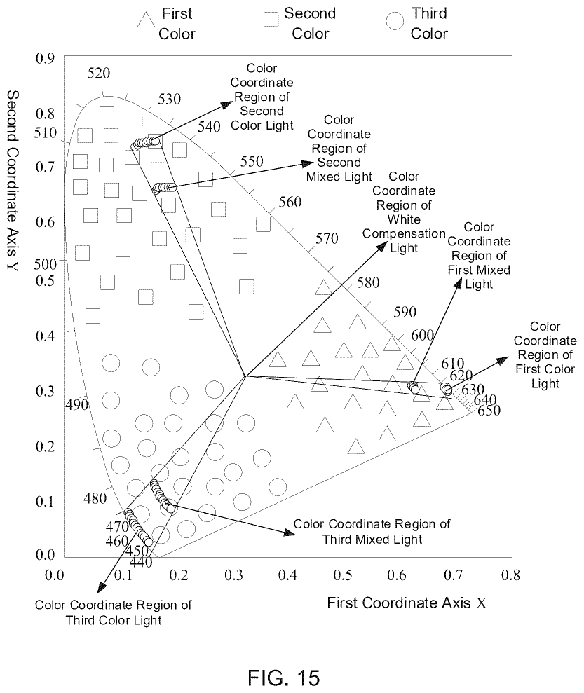

FIG. 14 to FIG. 16 are each a chromaticity diagram of light emitted by light-emitting units in the light-emitting substrate, in accordance with some embodiments.

In a scheme in which the compensation light-emitting unit 24 is not employed in the light-emitting substrate, the photoelectric properties of the plurality of first light-emitting units are in the same grade, in which a distance between a coordinate point of first color light emitted by one first light-emitting unit in the color coordinates and a coordinate point of first color light emitted by another first light-emitting unit in the color coordinates is less than or equal to 0.025 (e.g., equal to 0.020, 0.021, 0.022, 0.023, 0.024, or 0.025).

In some embodiments, as shown in FIG. 14 to FIG. 16, the plurality of light-emitting units 20 in the light-emitting substrate 100 include compensation light-emitting units 24, and a distance between a coordinate point of first color light emitted by one first light-emitting unit 21 in the color coordinates and a coordinate point of first color light emitted by another first light-emitting unit 21 in the color coordinates is greater than or equal to 0.035 (e.g., equal to 0.035, 0.038, 0.04, 0.042, 0.045, 0.05, 0.052, 0.055, 0.058, 0.06, or 0.065).

Since the compensation light emitted by the compensation light-emitting unit 24 can be mixed with the first color light, the chromaticity range of the display light emitted by the light-emitting substrate 100 is reduced, thereby improving the uniformity of the luminance and chromaticity of the light-emitting substrate 100, and thereby meeting the light-emitting uniformity requirements of the light-emitting substrate 100. In the embodiments of the present disclosure, on the basis that the use of the compensation light-emitting unit 24 can satisfy the light-emitting uniformity requirements of the light-emitting substrate 100, compared to the foregoing scheme in which the light-emitting substrate 100 does not employ the compensation light-emitting unit 24, the coordinate points of first color light emitted by any two first light-emitting units 21 in the color coordinates in the same light-emitting substrate 100 have a large distance therebetween, making it possible to allow the first color light emitted by the plurality of first light-emitting units 21 in the same light-emitting substrate 100 to have a large chromaticity range. Thus, it is possible to reduce the number of grades of the first light-emitting units 21 divided according to the chromaticity or even omit this division process at the stage of screening and grading, so that the utilization rate of the first light-emitting units 21 may be improved. In this way, the difficulty of screening the first light-emitting units 21 or the steps of screening the first light-emitting units 21 may be reduced, thereby improving the manufacturing efficiency of the light-emitting substrate 100.

In some examples, a distance between a coordinate point of first color light emitted by one first light-emitting unit 21 in the color coordinates and a coordinate point of first color light emitted by another first light-emitting unit 21 in the color coordinates is greater than or equal to 0.042 (e.g., equal to 0.042, 0.045, 0.05, 0.052, 0.055, 0.058, 0.06, or 0.065).

Compared to the foregoing scheme in which the light-emitting substrate 100 does not employ the compensation light-emitting unit 24, on the basis that the use of the compensation light-emitting unit 24 can satisfy the light-emitting uniformity requirements of the light-emitting substrate 100 in the present disclosure, the coordinate points of first color light emitted by any two first light-emitting units 21 in the color coordinates in the same light-emitting substrate 100 have a large distance therebetween, making it possible to allow the first color light emitted by the plurality of first light-emitting units 21 in the same light-emitting substrate 100 to have a large chromaticity range, thereby greatly reducing the number of grades of the first light-emitting units 21 divided according to the chromaticity, and thereby greatly improving the manufacturing efficiency of the light-emitting substrate 100 and the utilization rate of the first light-emitting units 21.

The parameters for dividing the grades according to the chromaticity of the light emitted by the light-emitting unit 20 in the light-emitting substrate 100 in some embodiments of the present disclosure are detailed in Table 2.

TABLE 2

| | Color | Range Value of | Range Value | Range Value of Color | | |
|---|---|---|---|---|---|---|
| | Coordinate | Color Coordinate | of MacAdam | Coordinate Value/Range | | Grade |
| Item | Axis | Value | Ellipse | Value of MacAdam Ellipse | | Number |
| First Color Light | X | 0.006 | 0.015 | 0.373 | (E1) | 1 |
| First Color Light | Y | 0.006 | 0.011 | 0.500 | (E2) | 1 |
| First Mixed Light | X | 0.005 | 0.014 | 0.323 | (F1) | 1 |
| First Mixed Light | Y | 0.004 | 0.011 | 0.404 | (F2) | 1 |
| Second Color Light | X | 0.059 | 0.020 | 2.94 | (G1) | 3 |
| Second Color Light | Y | 0.017 | 0.049 | 0.348 | (G2) | 1 |
| Second Mixed Light | X | 0.047 | 0.017 | 2.786 | (H1) | 3 |
| Second Mixed Light | Y | 0.014 | 0.039 | 0.345 | (H2) | 1 |
| Third Color Light | X | 0.012 | 0.002 | 5.087 | (M1) | 5 |
| Third Color Light | Y | 0.019 | 0.005 | 3.623 | (M2) | 4 |
| Third Mixed Light | X | 0.009 | 0.004 | 2.229 | (N1) | 2 |
| Third Mixed Light | Y | 0.015 | 0.011 | 1.463 | (N2) | 2 |

In Table 2, the “color coordinate axis” represents the first coordinate axis X or the second coordinate axis Y, and the “grade number” represents the number of divisions based on the chromaticity obtained by rounding off a ratio between a range value of a color coordinate value of the light emitted by the light-emitting unit and a range value of a corresponding MacAdam ellipse region.

The compensation light emitted by the compensation light-emitting unit 24 in the embodiments of the present disclosure can be used to form a first mixed light with the first color light, and based on the data in Table 2, it can be seen that the range value (i.e., the chromaticity range) of the color coordinate value of the first mixed light is slightly less than the range value of the color coordinate value of the first color light, and that the range value of the MacAdam ellipse region of the first mixed light is slightly less than the range value of the MacAdam ellipse region of the first color light, and thus the number of grades of the first light-emitting units 21 may be slightly reduced by employing the compensation light-emitting unit 24.

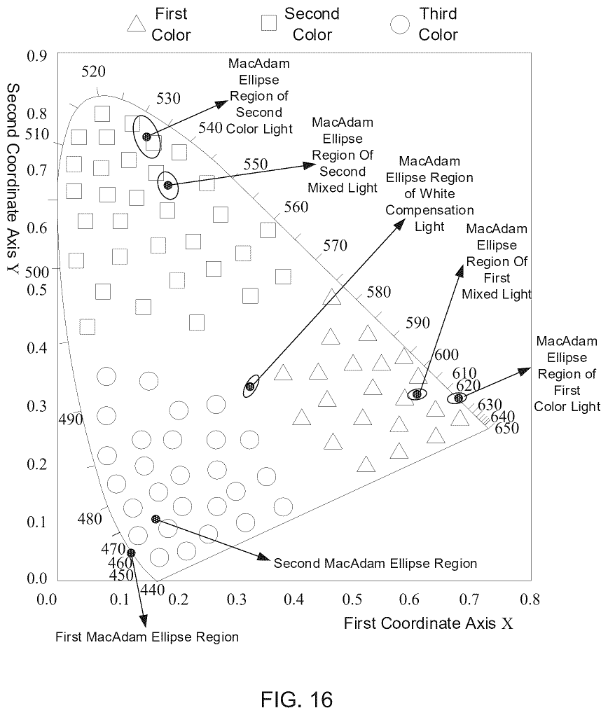

In some examples, as shown in FIG. 16, an area of the MacAdam ellipse region corresponding to the first color light emitted by the first light-emitting unit 21 may be greater than or equal to an area of the MacAdam ellipse region corresponding to the first mixed light of the first color light emitted by the first light-emitting unit 21 and the compensation light emitted by the corresponding compensation light-emitting unit 24.

It will be noted that the MacAdam ellipse region can be understood as a chromaticity range that cannot be perceived by the human eyes in the chromaticity diagram. The MacAdam ellipse may include an N-step MacAdam ellipse, where N is an integer greater than or equal to 1. Here, the N-step MacAdam ellipse region can be understood as a chromaticity range that is N times away from s target color in the chromaticity diagram and cannot be perceived by the human eyes.

Combined with the data in Table 2, it can be seen that the use of the compensation light-emitting unit 24 in the embodiments of the present disclosure may make the area of the MacAdam ellipse region corresponding to the first mixed light small, and may reduce the chromaticity range of the first mixed light in the display light emitted by the display panel 1000 that is imperceptible to the human eyes, thereby improving the uniformity of the luminance and chromaticity of the light-emitting substrate 100 and the display panel 1000. On the basis of improving the uniformity of the luminance and chromaticity of the light-emitting substrate 100, an acceptable chromaticity range of the plurality of first light-emitting units 21 in the same light-emitting substrate 100 may be broadened, the number of grades of the first light-emitting units 21 divided according to the chromaticity may be slightly reduced, and the difficulty of screening the first light-emitting units 21 may be reduced, thereby improving the manufacturing efficiency of the light-emitting substrate 100 and the utilization rate of the first light-emitting units 21.

For example, as shown in FIG. 16, a range value of a 5-step MacAdam ellipse region corresponding to the first color light on the first coordinate axis X in the color coordinates may be greater than or equal to a range value of a 5-step MacAdam ellipse region corresponding to the first mixed light on the first coordinate axis X in the color coordinates.

For example, as shown in FIG. 16, a range value of a 5-step MacAdam ellipse region corresponding to the first color light on the second coordinate axis Y in the color coordinates may be greater than or equal to a range value of a 5-step MacAdam ellipse region corresponding to the first mixed light on second first coordinate axis Y in the color coordinates.

In this way, the range value of the 5-step MacAdam ellipse region corresponding to the first mixed light in the color coordinates is small, and the area of the MacAdam ellipse region corresponding to the first mixed light may be reduced, thereby improving the uniformity of the luminance and chromaticity of the display panel 1000. On the basis of improving the uniformity of the luminance and chromaticity of the light-emitting substrate 100, the number of grades of the first light-emitting units 21 divided according to the chromaticity may be greatly reduced, and the difficulty of screening the first light-emitting units 21 may be reduced, thereby greatly improving the manufacturing efficiency of the light-emitting substrate 100 and the utilization rate of the first light-emitting units 21.

In some examples, based on the data in Table 2, it can be seen that a ratio of the range value of the first color light on the first coordinate axis X in the color coordinates to the range value of the MacAdam ellipse region corresponding to the first color light on the first coordinate axis X is E1, and a ratio of the range value of the first mixed light on the first coordinate axis X in the color coordinates to the range value of the MacAdam ellipse region corresponding to the first mixed light on the first coordinate axis X is F1, where E1 is slightly greater than F1.

In some examples, based on the data in Table 2, it can be seen that a ratio of the range value of the first color light on the second coordinate axis Y in the color coordinates to the range value of the MacAdam ellipse region corresponding to the first color light on the second coordinate axis Y is E2, and a ratio of the range value of the first mixed light on the second coordinate axis Y in the color coordinates to the range value of the MacAdam ellipse region corresponding to the first mixed light on the second coordinate axis Y is F2, where E2 is slightly greater than F2.

In this way, the first color light can be mixed with the compensation light emitted by the compensation light-emitting unit 24 corresponding to the first light-emitting unit 21, and the compensation light-emitting unit 24 can compensate for the luminance of the first light-emitting unit 21, so as to improve the uniformity of the luminance and chromaticity of the light-emitting substrate 100, thereby improving the display effect of the display panel 1000. On the basis of improving the uniformity of the luminance and chromaticity of the light-emitting substrate 100, the number of grades of the first light-emitting units 21 divided according to the luminance and chromaticity may be slightly reduced, and the color gamut coverage area of the display panel 1000 may be ensured.

In some embodiments, in different pixel unit regions, a ratio of an emission luminance of the compensation light-emitting unit 24 to an emission luminance of the first light-emitting unit 21 is substantially the same. For example, in different pixel unit regions, a ratio of an emission luminance of the first compensation light-emitting unit 241 to an emission luminance of the first light-emitting unit 21 is substantially the same.

In some examples, a ratio between a ratio of an emission luminance of a first compensation light-emitting unit 241 to an emission luminance of a first light-emitting unit 21 in one pixel unit region and a ratio of an emission luminance of a first compensation light-emitting unit 241 to an emission luminance of a first light-emitting unit 21 in another pixel unit region may be in a range from 0.8 to 1.2 (including the boundary values at both ends).

In this way, the compensation effect of the emission luminance of the compensation light-emitting unit 24 on the emission luminance of the first light-emitting unit 21 is substantially the same, and the luminance uniformity of the first color light emitted by the light-emitting substrate 100 may be ensured on the basis of increasing the luminance of the first color light emitted by the light-emitting substrate 100; moreover, the range value of the first mixed light of the compensation light emitted by the compensation light-emitting unit 24 and the first color light emitted by the first light-emitting unit 21 in the color coordinates may be reduced, thereby reducing the chromaticity range of the display light emitted by the light-emitting substrate 100, and improving the chromaticity uniformity of the light-emitting substrate 100 and the display panel 1000. On the basis of improving the uniformity of the luminance and chromaticity of the light-emitting substrate 100, an acceptable chromaticity range of the plurality of first light-emitting units 21 in the same light-emitting substrate 100 may be broadened, and the number of grades of the first light-emitting units 21 divided according to the chromaticity may be reduced.

In some examples, a ratio of an emission luminance of the compensation light-emitting unit 24 to an emission luminance of the first light-emitting unit 21 may be greater than or equal to 10% and less than or equal to 50% (e.g., equal to 10%, 15%, 20%, 25%, 30%, 35%, 40%, 45%, or 50%).

By limiting the ratio of the emission luminance of the compensation light-emitting unit 24 to the emission luminance of the first light-emitting unit 21 within a reasonable range, the luminance of the light-emitting substrate 100 may be increased; moreover, the range value of the first mixed light of the compensation light emitted by the compensation light-emitting unit 24 and the first color light emitted by the first light-emitting unit 21 in the color coordinates may be reduced, thereby reducing the chromaticity range of the display light emitted by the light-emitting substrate 100, and improving the chromaticity uniformity of the light-emitting substrate 100 and the display panel 1000. On the basis of improving the uniformity of the luminance and chromaticity of the light-emitting substrate 100, an acceptable chromaticity range of the plurality of first light-emitting units 21 in the same light-emitting substrate 100 may be broadened, and the number of grades of the first light-emitting units 21 divided according to the chromaticity may be reduced.

For example, the ratio of the emission luminance of the compensation light-emitting unit 24 to the emission luminance of the first light-emitting unit 21 may be greater than or equal to 10% and less than or equal to 30% (e.g., equal to 10%, 12%, 15%, 16%, 20%, 23%, 25%, 27%, 29%, or 30%).

In this way, the chromaticity range of the light emitted by the light-emitting substrate 100 may be greatly reduced on the basis of reasonably increasing the luminance of the light emitted by the light-emitting substrate 100, thereby greatly improving the chromaticity uniformity of the light-emitting substrate 100 and the display panel 1000. On the basis of greatly improving the chromaticity uniformity of the light-emitting substrate 100, an acceptable chromaticity range of the plurality of first light-emitting units 21 in the same light-emitting substrate 100 may be broadened, and the number of grades of the first light-emitting units 21 divided according to the luminance and chromaticity may be greatly reduced.

In the light-emitting substrate of some embodiments of the present disclosure, in a case where the compensation light-emitting unit and the corresponding light-emitting unit have a different luminance ratio, the grade parameters of the light-emitting units divided according to the chromaticity are detailed in Table 3.

TABLE 3

| Luminance Ratio of | Grade Number of | Grade Number of | Grade Number of | Total Grade |
|---|---|---|---|---|
| Compensation Light- | First Light-Emitting | Second Light- | Third Light- | Number of Light- |
| Emitting Unit | Units | Emitting Units | Emitting Units | Emitting Units |
| 0 | 1 | 3 | 20 | 60 |
| 10% | 1 | 3 | 8 | 24 |
| 20% | 1 | 3 | 4 | 12 |
| 30% | 1 | 3 | 4 | 12 |
| 40% | 1 | 3 | 1 | 3 |
| 50% | 1 | 3 | 1 | 3 |

Based on the data in Table 2 and the data in Table 3, it can be seen that in the method of compensating the luminance of the corresponding light-emitting unit 20 by using the luminance of the compensation light-emitting unit 24 in different ratios in the present disclosure, the number of grades of the light-emitting units 20 of different colors is reduced to different extents. In the present disclosure, the extent of reduction in the number of grades of the third light-emitting units 23 is greater than the extent of reduction in the number of grades of the first light-emitting units 21 and the extent of reduction in the number of grades of the second light-emitting units 22.

In some embodiments, a light-emitting area of the compensation light-emitting unit 24 may be substantially equal to a light-emitting area of the first light-emitting unit 24. For example, a ratio between the light-emitting area of the compensation light-emitting unit 24 and the light-emitting area of the first light-emitting unit 21 may be in a range from 0.8 to 1.2 (including the boundary values at both ends).

For example, both the light-emitting area of the compensation light-emitting unit 24 and the light-emitting area of the first light-emitting unit 21 may be less than or equal to 0.020 mm² (e.g., equal to 0.010 mm², 0.012 mm², 0.014 mm², 0.016 mm², 0.018 mm2, or 0.020 mm²).

In this way, it is convenient to arrange the compensation light-emitting unit 24 on the base substrate 10, and the compensation light emitted by the compensation light-emitting unit 24 and the first color light emitted by the first light-emitting unit 21 in the light-emitting substrate 100 can be evenly distributed, thereby improving the display effect of the light-emitting substrate 100 and the display panel 1000.

In a scheme in which the compensation light-emitting unit 24 is not employed in the light-emitting substrate, the photoelectric properties of the plurality of second light-emitting units are in the same grade, in which a distance between a coordinate point of second color light emitted by one second light-emitting unit in the color coordinates and a coordinate point of second color light emitted by another second light-emitting unit in the color coordinates is less than or equal to 0.015 (e.g., equal to 0.010, 0.011, 0.012, 0.013, 0.014, or 0.015).

In some embodiments, the plurality of light-emitting units 20 in the light-emitting substrate 100 include compensation light-emitting units 24, and a distance between a coordinate point of second color light emitted by one second light-emitting unit 22 in the color coordinates and a coordinate point of second color light emitted by another second light-emitting unit 22 in the color coordinates is greater than or equal to 0.023 (e.g., equal to 0.023, 0.025, 0.026, 0.028, 0.029, 0.03, 0.032, or 0.035).

Since the compensation light emitted by the compensation light-emitting unit 24 can be mixed with the second color light, the chromaticity range of the display light emitted by the light-emitting substrate 100 is reduced, thereby improving the uniformity of the luminance and chromaticity of the light-emitting substrate 100, and thereby meeting the light-emitting uniformity requirements of the light-emitting substrate 100. In the embodiments of the present disclosure, on the basis that the use of the compensation light-emitting unit 24 can satisfy the light-emitting uniformity requirements of the light-emitting substrate 100, compared to the foregoing scheme in which the light-emitting substrate 100 does not employ the compensation light-emitting unit 24, the coordinate points of second color light emitted by any two second light-emitting units 22 in the color coordinates in the same light-emitting substrate 100 have a large distance therebetween, making it possible to allow the second color light emitted by the plurality of second light-emitting units 22 in the same light-emitting substrate 100 to have a large chromaticity range. Thus, it is possible to reduce the number of grades of the second light-emitting units 22 divided according to the chromaticity at the stage of screening and grading, so that the utilization rate of the second light-emitting units 22 may be improved. In this way, the difficulty of screening the second light-emitting units 22 or the steps of screening the second light-emitting units 22 may be reduced, thereby improving the manufacturing efficiency of the light-emitting substrate 100.

In some examples, a distance between a coordinate point of second color light emitted by one second light-emitting unit 22 in the color coordinates and a coordinate point of second color light emitted by another second light-emitting unit 22 in the color coordinates is greater than or equal to 0.026 (e.g., equal to 0.026, 0.027, 0.028, 0.029, 0.03, 0.031, 0.032, 0.033, or 0.035).

Compared to the foregoing scheme in which the light-emitting substrate 100 does not employ the compensation light-emitting unit 24, on the basis that the use of the compensation light-emitting unit 24 can satisfy the light-emitting uniformity requirements of the light-emitting substrate 100 in the present disclosure, the coordinate points of second color light emitted by any two second light-emitting units 22 in the color coordinates in the same light-emitting substrate 100 have a large distance therebetween, making it possible to allow the second color light emitted by the plurality of second light-emitting units 22 in the same light-emitting substrate 100 to have a large chromaticity range, thereby greatly reducing the number of grades of the second light-emitting units 22 divided according to the chromaticity, and thereby greatly improving the manufacturing efficiency of the light-emitting substrate 100 and the utilization rate of the second light-emitting units 22.

In some examples, as shown in FIG. 16 and Table 2, an area of the MacAdam ellipse region corresponding to the second color light emitted by the second light-emitting unit 22 may be greater than or equal to an area of the MacAdam ellipse region corresponding to the second mixed light of the second color light emitted by the second light-emitting unit 22 and the compensation light emitted by the corresponding compensation light-emitting unit 24.

Combined with the data in Table 2, it can be seen that the use of the compensation light-emitting unit 24 in the embodiments of the present disclosure may make the area of the MacAdam ellipse region corresponding to the second mixed light small, and may reduce the chromaticity range of the second mixed light in the display light emitted by the light-emitting substrate 100 and the display panel 1000 that is imperceptible to the human eyes, thereby improving the uniformity of the luminance and chromaticity of the light-emitting substrate 100 and the display panel 1000. On the basis of improving the uniformity of the luminance and chromaticity of the light-emitting substrate 100, an acceptable chromaticity range of the plurality of second light-emitting units 22 in the same light-emitting substrate 100 may be broadened, the number of grades of the second light-emitting units 22 divided according to the chromaticity may be slightly reduced, and the difficulty of screening the second light-emitting units 22 may be reduced, thereby improving the manufacturing efficiency of the light-emitting substrate 100 and the utilization rate of the second light-emitting units 22.

For example, as shown in FIG. 16, a range value of a 5-step MacAdam ellipse region corresponding to the second color light on the first coordinate axis X in the color coordinates may be greater than or equal to a range value of a 5-step MacAdam ellipse region corresponding to the second mixed light on the first coordinate axis X in the color coordinates.

In this way, the range value of the MacAdam ellipse region of the second mixed light is small, and the area of the MacAdam ellipse region corresponding to the second mixed light may be reduced, thereby improving the uniformity of the luminance and chromaticity of the light-emitting substrate 100 and the display panel 1000. On the basis of improving the uniformity of the luminance and chromaticity of the light-emitting substrate 100, an acceptable chromaticity range of the plurality of second light-emitting units 22 in the same light-emitting substrate 100 may be broadened, the number of grades of the second light-emitting units 22 divided according to the chromaticity may be greatly reduced, and the difficulty of screening the second light-emitting units 22 may be reduced, thereby greatly improving the manufacturing efficiency of the light-emitting substrate 100 and the utilization rate of the second light-emitting units 22.

In some examples, based on the data in Table 2, it can be seen that a ratio of the range value of the second color light on the first coordinate axis X in the color coordinates to the range value of the MacAdam ellipse region corresponding to the second color light on the first coordinate axis X is G1, and a ratio of the range value of the second mixed light on the first coordinate axis X in the color coordinates to the range value of the MacAdam ellipse region corresponding to the second mixed light on the first coordinate axis X is H1, where G1 is slightly greater than H1.

In some examples, based on the data in Table 2, it can be seen that a ratio of the range value of the second color light on the second coordinate axis Y in the color coordinates to the range value of the MacAdam ellipse region corresponding to the second color light on the second coordinate axis Y is G2, and a ratio of the range value of the second mixed light on the second coordinate axis Y in the color coordinates to the range value of the MacAdam ellipse region corresponding to the second mixed light on the second coordinate axis Y is H2, where G2 is slightly greater than H2.

In this way, the second color light can be mixed with the compensation light emitted by the compensation light-emitting unit 24 corresponding to the second light-emitting unit 22, and the compensation light-emitting unit 24 can compensate for the luminance of the second light-emitting unit 22, thereby improving the display effect of the display panel 1000. On the basis of improving the luminance of the second light-emitting unit 22, an acceptable chromaticity range of the plurality of second light-emitting units 22 in the same light-emitting substrate 100 may be broadened, the number of grades of the second light-emitting units 22 divided according to the luminance and chromaticity may be slightly reduced, and the color gamut coverage area of the display panel 1000 may be ensured.

In some embodiments, in different pixel unit regions, a ratio of an emission luminance of the compensation light-emitting unit 24 to an emission luminance of the second light-emitting unit 22 is substantially the same. For example, in different pixel unit regions, a ratio of an emission luminance of the second compensation light-emitting unit 242 to an emission luminance of the second light-emitting unit 22 is substantially the same.

In some examples, a ratio between a ratio of an emission luminance of a second compensation light-emitting unit 242 to an emission luminance of a second light-emitting unit 22 in one pixel unit region and a ratio of an emission luminance of a second compensation light-emitting unit 242 to an emission luminance of a second light-emitting unit 22 in another pixel unit region may be in a range from 0.8 to 1.2 (including the boundary values at both ends).

In this way, in different pixel unit regions, the compensation effect of the emission luminance of the compensation light-emitting unit 24 on the emission luminance of the second light-emitting unit 22 is substantially the same, and the luminance uniformity of the second color light emitted by the light-emitting substrate 100 may be ensured on the basis of increasing the luminance of the second color light emitted by the light-emitting substrate 100; moreover, the range value of the second mixed light of the compensation light emitted by the compensation light-emitting unit 24 and the second color light emitted by the second light-emitting unit 22 in the color coordinates may be reduced, thereby improving the chromaticity uniformity of the light-emitting substrate 100 and the display panel 1000. On the basis of improving the uniformity of the luminance and chromaticity of the light-emitting substrate 100, an acceptable chromaticity range of the plurality of second light-emitting units 22 in the same light-emitting substrate 100 may be broadened, and the number of grades of the second light-emitting units 22 divided according to the chromaticity may be reduced.

In some examples, a ratio of an emission luminance of the compensation light-emitting unit 24 to an emission luminance of the second light-emitting unit 22 may be greater than or equal to 10% and less than or equal to 50% (e.g., equal to 10%, 15%, 20%, 25%, 30%, 35%, 40%, 45%, or 50%).

By limiting the ratio of the emission luminance of the compensation light-emitting unit 24 to the emission luminance of the second light-emitting unit 22 within a reasonable range, the luminance of the light-emitting substrate 100 may be increased; moreover, the range value of the second mixed light of the compensation light emitted by the compensation light-emitting unit 24 and the second color light emitted by the second light-emitting unit 22 in the color coordinates may be reduced, thereby reducing the chromaticity range of the display light emitted by the light-emitting substrate 100, and improving the chromaticity uniformity of the light-emitting substrate 100 and the display panel 1000. On the basis of improving the uniformity of the luminance and chromaticity of the light-emitting substrate 100, an acceptable chromaticity range of the plurality of second light-emitting units 22 in the same light-emitting substrate 100 may be broadened, and the number of grades of the second light-emitting units 22 divided according to the chromaticity may be reduced.

For example, the ratio of the emission luminance of the compensation light-emitting unit 24 to the emission luminance of the second light-emitting unit 22 may be greater than or equal to 10% and less than or equal to 30% (e.g., equal to 10%, 12%, 15%, 16%, 20%, 23%, 25%, 27%, 29%, or 30%).

In this way, the chromaticity range of the light emitted by the light-emitting substrate 100 may be greatly reduced on the basis of reasonably increasing the luminance of the light emitted by the light-emitting substrate 100, thereby greatly improving the chromaticity uniformity of the light-emitting substrate 100 and the display panel 1000. On the basis of greatly improving the chromaticity uniformity of the light-emitting substrate 100, an acceptable chromaticity range of the plurality of second light-emitting units 22 in the same light-emitting substrate 100 may be broadened, and the number of grades of the second light-emitting units 22 divided according to the luminance and chromaticity may be greatly reduced.

In some embodiments, a light-emitting area of the compensation light-emitting unit 24 may be substantially equal to a light-emitting area of the second light-emitting unit 22. For example, a ratio between the light-emitting area of the compensation light-emitting unit 24 and the light-emitting area of the second light-emitting unit 22 may be in a range from 0.8 to 1.2 (including the boundary values at both ends).

For example, both the light-emitting area of the compensation light-emitting unit 24 and the light-emitting area of the second light-emitting unit 22 may be less than or equal to 0.020 mm² (e.g., equal to 0.010 mm², 0.012 mm², 0.014 mm², 0.016 mm², 0.018 mm2, or 0.020 mm²).

In this way, it is convenient to arrange the compensation light-emitting unit 24 on the base substrate 10, and the compensation light emitted by the compensation light-emitting unit 24 and the second color light emitted by the second light-emitting unit 22 in the light-emitting substrate 100 can be evenly distributed, thereby improving the display effect of the light-emitting substrate 100 and the display panel 1000.

In a scheme in which the compensation light-emitting unit 24 is not employed in the light-emitting substrate, the photoelectric properties of the plurality of third light-emitting units are in the same grade, in which a distance between a coordinate point of third color light emitted by one third light-emitting unit in the color coordinates and a coordinate point of third color light emitted by another third light-emitting unit in the color coordinates is less than or equal to 0.003 (e.g., equal to 0.001, 0.002 or 0.003).

In some embodiments, the plurality of light-emitting units 20 in the light-emitting substrate 100 include compensation light-emitting units 24, and a distance between a coordinate point of third color light emitted by one third light-emitting unit 23 in the color coordinates and a coordinate point of third color light emitted by another third light-emitting unit 23 in the color coordinates is greater than or equal to 0.005 (e.g., equal to 0.005, 0.006, 0.007, 0.008, 0.009, 0.010, 0.012, or 0.015).

Since the compensation light emitted by the compensation light-emitting unit 24 can be mixed with the third color light, the chromaticity range of the display light emitted by the light-emitting substrate 100 is reduced, thereby improving the uniformity of the luminance and chromaticity of the light-emitting substrate 100, and thereby meeting the light-emitting uniformity requirements of the light-emitting substrate 100. In the embodiments of the present disclosure, on the basis that the use of the compensation light-emitting unit 24 can satisfy the light-emitting uniformity requirements of the light-emitting substrate 100, compared to the foregoing scheme in which the light-emitting substrate 100 does not employ the compensation light-emitting unit 24, the coordinate points of third color light emitted by any two third light-emitting units 23 in the color coordinates in the same light-emitting substrate 100 have a large distance therebetween, making it possible to allow the third color light emitted by the plurality of third light-emitting units 23 in the same light-emitting substrate 100 to have a large chromaticity range. Thus, it is possible to reduce the number of grades of the third light-emitting units 23 divided according to the chromaticity at the stage of screening and grading, so that the utilization rate of the third light-emitting units 23 may be improved. In this way, the difficulty of screening the third light-emitting units 23 or the steps of screening the third light-emitting units 23 may be reduced, thereby improving the manufacturing efficiency of the light-emitting substrate 100.

In some examples, a distance between a coordinate point of third color light emitted by one third light-emitting unit 23 in the color coordinates and a coordinate point of third color light emitted by another third light-emitting unit 23 in the color coordinates is greater than or equal to 0.007 (e.g., equal to 0.007, 0.008, 0.009, 0.010, 0.012, 0.015, or 0.018).

Compared to the foregoing scheme in which the light-emitting substrate 100 does not employ the compensation light-emitting unit 24, on the basis that the use of the compensation light-emitting unit 24 can satisfy the light-emitting uniformity requirements of the light-emitting substrate 100 in the present disclosure, the coordinate points of third color light emitted by any two third light-emitting units 23 in the color coordinates in the same light-emitting substrate 100 have a large distance therebetween, making it possible to allow the third color light emitted by the plurality of third light-emitting units 23 in the same light-emitting substrate 100 to have a large chromaticity range, thereby greatly reducing the number of grades of the third light-emitting units 23 divided according to the chromaticity, and thereby greatly improving the manufacturing efficiency of the light-emitting substrate 100 and the utilization rate of the third light-emitting units 23.

In some examples, as shown in FIG. 16, an area of a first MacAdam ellipse region corresponding to third color light emitted by the third light-emitting unit 23 may be less than an area of a second MacAdam ellipse region corresponding to mixed light (i.e., third mixed light) formed by the third color light emitted by the third light-emitting unit 23 and compensation light emitted by the corresponding compensation light-emitting unit 24.

Combined with the data in Table 2, it can be seen that the use of the compensation light-emitting unit 24 in the embodiments of the present disclosure may make the area of the second MacAdam ellipse region corresponding to the third mixed light large, and may increase the chromaticity range of the third mixed light in the display light emitted by the display panel 1000 that is imperceptible to the human eyes, thereby improving the uniformity of the luminance and chromaticity of the light-emitting substrate 100 and the display panel 1000. On the basis of improving the uniformity of the luminance and chromaticity of the light-emitting substrate 100, an acceptable chromaticity range of the plurality of third light-emitting units 23 in the same light-emitting substrate 100 may be broadened, the number of grades of the third light-emitting units 23 divided according to the chromaticity may be reduced, and the difficulty of screening the third light-emitting units 23 may be reduced, thereby improving the manufacturing efficiency of the light-emitting substrate 100 and the utilization rate of the third light-emitting units 23.

For example, as shown in FIG. 16, a range value of a 5-step first MacAdam ellipse region corresponding to the third color light on the first coordinate axis X in the color coordinates may be less than a range value of a 5-step second MacAdam ellipse region corresponding to the third mixed light on the first coordinate axis X in the color coordinates.

For example, as shown in FIG. 16, a range value of a 5-step first MacAdam ellipse region corresponding to the third color light on the second coordinate axis Y in the color coordinates may be less than a range value of a 5-step second MacAdam ellipse region corresponding to the third mixed light on the second coordinate axis Y in the color coordinates.

In this way, the range value of the 5-step second MacAdam ellipse region of the third mixed light is large, and the area of the 5-step second MacAdam ellipse region corresponding to the third mixed light may be increased, thereby improving the uniformity of the luminance and chromaticity of the light-emitting substrate 100 and the display panel 1000. On the basis of improving the uniformity of the luminance and chromaticity of the light-emitting substrate 100, an acceptable chromaticity range of the plurality of third light-emitting units 23 in the same light-emitting substrate 100 may be broadened, the number of grades of the third light-emitting units 23 divided according to the chromaticity may be greatly reduced, thereby improving the utilization rate of the third light-emitting units 23.

In some examples, based on the data in Table 2, it can be seen that a ratio of a range value of the third color light on the first coordinate axis X in the color coordinates to a range value of the first MacAdam ellipse region on the first coordinate axis X is M1, and a ratio of a range value of the mixed light of the third color light and the compensation light on the first coordinate axis X in the color coordinates to a range value of the second MacAdam ellipse region on the first coordinate axis X is N1, where M1 may be greater than N1.

In some examples, based on the data in Table 2, it can be seen that a ratio of a range value of the third color light on the second coordinate axis Y in the color coordinates to a range value of the first MacAdam ellipse region on the second coordinate axis Y is M2, and a ratio of a range value of the mixed light of the third color light and the compensation light on the second coordinate axis Y in the color coordinates to a range value of the second MacAdam ellipse region on the second coordinate axis Y is N2, where M2 may greater than N2.

In this way, the third color light can be mixed with the compensation light emitted by the compensation light-emitting unit 24 corresponding to the third light-emitting unit 23, and the compensation light-emitting unit 24 can compensate for the luminance of the third light-emitting unit 23, so as to improve the uniformity of the luminance and chromaticity of the light-emitting substrate 100, thereby improving the display effect of the display panel 1000. On the basis of improving the uniformity of the luminance and chromaticity of the light-emitting substrate 100, an acceptable chromaticity range of the plurality of third light-emitting units 23 in the same light-emitting substrate 100 may be broadened, and the number of grades of the third light-emitting units 23 divided according to M2 and N2 may be reduced, thereby improving the mass production feasibility of the display panel 1000 and the utilization rate of the third light-emitting units 23.

In some embodiments, in different pixel unit regions, a ratio of an emission luminance of the compensation light-emitting unit 24 to an emission luminance of the third light-emitting unit 23 is substantially the same. For example, in different pixel unit regions, a ratio of an emission luminance of the third compensation light-emitting unit 243 to an emission luminance of the third light-emitting unit 23 is substantially the same.

In some examples, a ratio between a ratio of an emission luminance of a third compensation light-emitting unit 243 to an emission luminance of a third light-emitting unit 23 in one pixel unit region and a ratio of an emission luminance of a third compensation light-emitting unit 243 to an emission luminance of a third light-emitting unit 23 in another pixel unit region may be in a range from 0.8 to 1.2 (including the boundary values at both ends).

In this way, the compensation effect of the emission luminance of the compensation light-emitting unit 24 on the emission luminance of the third light-emitting unit 23 is substantially the same, and the luminance uniformity of the third color light emitted by the light-emitting substrate 100 may be ensured on the basis of increasing the luminance of the third color light emitted by the light-emitting substrate 100; moreover, the range value of the third mixed light of the compensation light emitted by the compensation light-emitting unit 24 and the third color light emitted by the third light-emitting unit 23 in the color coordinates may be reduced, so as to reduce the chromaticity range of the third color light emitted by the light-emitting substrate 100, thereby improving the chromaticity uniformity of the light-emitting substrate 100 and the display panel 1000. On the basis of improving the uniformity of the luminance and chromaticity of the light-emitting substrate 100, an acceptable chromaticity range of the plurality of third light-emitting units 23 in the same light-emitting substrate 100 may be broadened, and the number of grades of the third light-emitting units 23 divided according to the chromaticity may be reduced.

In some examples, in the pixel unit region, a ratio of an emission luminance of the compensation light-emitting unit 24 to an emission luminance of the third light-emitting unit 23 may be greater than or equal to 10% and less than or equal to 50% (e.g., equal to 10%, 15%, 20%, 25%, 30%, 35%, 40%, 45%, or 50%).

By limiting the ratio of the emission luminance of the compensation light-emitting unit 24 to the emission luminance of the third light-emitting unit 23 within a reasonable range, the luminance of the light-emitting substrate 100 may be increased; moreover, the range value of the third mixed light of the compensation light emitted by the compensation light-emitting unit 24 and the third color light emitted by the third light-emitting unit 23 in the color coordinates may be reduced, thereby reducing the number of grades of the third light-emitting units 23 divided according to the luminance and chromaticity, so as to improve the utilization rate of the third light-emitting units 23. Furthermore, since the chromaticity range of the display light emitted by the display panel 1000 is reduced, the chromaticity uniformity of the display light emitted by the display panel 1000 may be improved.

For example, in the pixel unit region, the ratio of the emission luminance of the compensation light-emitting unit 24 to the emission luminance of the third light-emitting unit 23 may be greater than or equal to 10% and less than or equal to 30% (e.g., equal to 10%, 12%, 15%, 16%, 20%, 23%, 25%, 27%, 29%, or 30%).

In this way, the chromaticity range of the third mixed light emitted by the light-emitting substrate 100 may be greatly reduced on the basis of reasonably increasing the luminance of the third color light emitted by the light-emitting substrate 100, thereby greatly reducing the number of grades of the third light-emitting units 23 divided according to the luminance and chromaticity, so as to improve the utilization rate of the third light-emitting units 23.

In some embodiments, a light-emitting area of the compensation light-emitting unit 24 may be substantially equal to a light-emitting area of the third light-emitting unit 23. For example, a ratio between the light-emitting area of the compensation light-emitting unit 24 and the light-emitting area of the third light-emitting unit 23 may be in a range from 0.8 to 1.2 (including the boundary values at both ends).

For example, both the light-emitting area of the compensation light-emitting unit 24 and the light-emitting area of the third light-emitting unit 23 may be less than or equal to 0.020 mm² (e.g., equal to 0.010 mm², 0.012 mm², 0.014 mm², 0.016 mm², 0.018 mm2, or 0.020 mm²).

In this way, it is convenient to arrange the compensation light-emitting unit 24 on the base substrate 10, and the compensation light emitted by the compensation light-emitting unit 24 and the third color light emitted by the third light-emitting unit 23 in the light-emitting substrate 100 can be evenly distributed, thereby improving the display effect of the light-emitting substrate 100 and the display panel 1000.

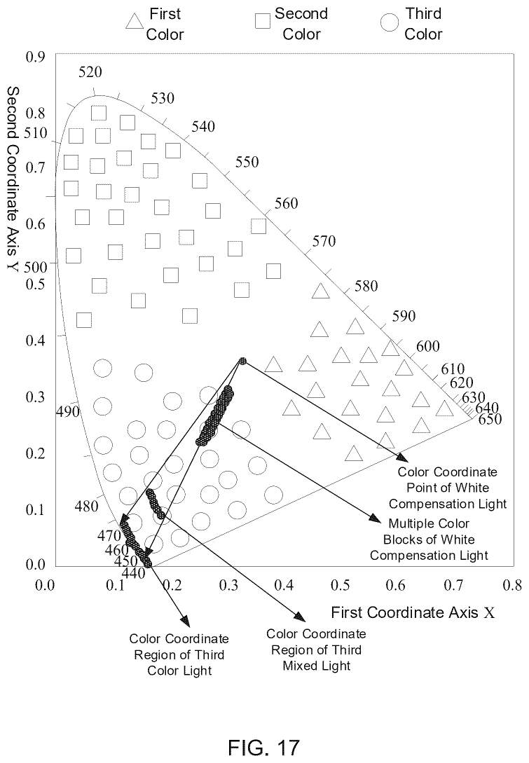

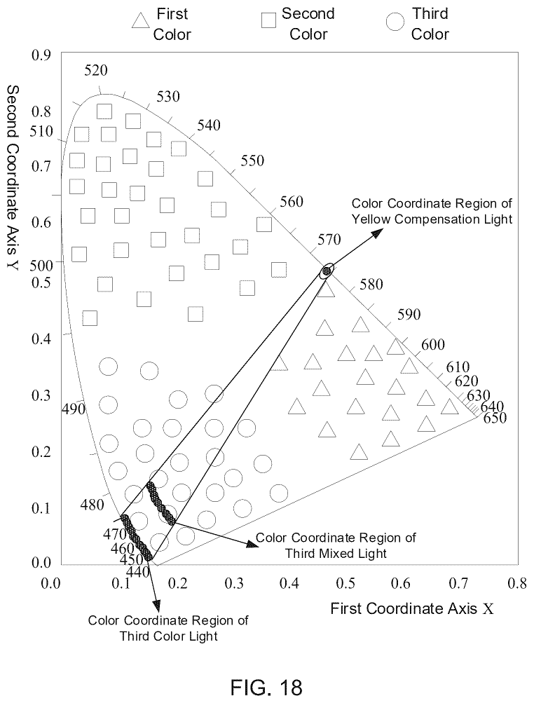

FIG. 17 is a chromaticity diagram of light emitted by the third light-emitting unit and the compensation light-emitting unit in the light-emitting substrate, in accordance with some embodiments. FIG. 18 is another chromaticity diagram of light emitted by the third light-emitting unit and the compensation light-emitting unit in the light-emitting substrate, in accordance with some embodiments.

In some embodiments, as shown in FIG. 17 and FIG. 18, a color coordinate point of the compensation light may be located within a region enclosed by lines connecting a color coordinate point of the first color, a color coordinate point of the second color, and a color coordinate point of the third color. In the chromaticity diagram, the color coordinate point of the compensation light emitted by the compensation light-emitting unit 24 in the color coordinates is located within a region enclosed by lines connecting a first color coordinate point (0.3275, 0.3577), a second color coordinate point (0.3750, 0.6250), and a third color coordinate point (0.6000, 0.4000), where the first color coordinate point may represent 5700K white compensation light.

In some examples, the compensation light may be white compensation light. The coordinate point of the compensation light emitted by the compensation light-emitting unit 24 in the color coordinates may be located within a first color coordinate region (not shown in the figure), where the first color coordinate region may be composed of lines connecting three color coordinate points. The color coordinate value of the first color coordinate point may be (0.3275, 0.3577), and the color coordinate values of the other two color coordinate points in the first color coordinate region may be (0.2530, 0.2000) and (0.2250, 0.2250).

For example, the coordinate point of the compensation light emitted by the compensation light-emitting unit 24 in the color coordinates may be located within a region enclosed by lines connecting a first color coordinate point (0.3275, 0.3577), a fourth color coordinate point (0.2800, 0.2500), and a fifth color coordinate point (0.2600, 0.2600).

According to the principle of light mixing, the closer the color coordinate point of the compensation light is to a color coordinate point of light emitted by a light-emitting unit 20 to be compensated, the higher the luminance of the compensation light is. By limiting the color coordinate point of the compensation light within a reasonable range, the luminance of the white compensation light can also be limited within a reasonable range, avoiding the problem of difficulty in adjusting the white balance caused by an excessively high amount of light from the white compensation light, and thus the emission luminance of the light-emitting substrate 100 may be reasonably increased. Furthermore, by limiting the color coordinate value of the white compensation light within the reasonable range, the chromaticity range of the monochromatic light emitted by the light-emitting substrate 100 can be reasonably limited, so that the chromaticity uniformity of the display light emitted by the light-emitting substrate 100 may be improved.

In some examples, as shown in FIG. 17, in the chromaticity diagram, the region of the color coordinate value of the white compensation light can be roughly evenly divided into 10 color blocks, and color coordinate values of a plurality of rays of white compensation light emitted by the plurality of compensation light-emitting units 24 in the display panel 1000 can be located within a single color block. For example, each color block may have a roughly parallelogram shape. For example, four color coordinate points of the color block of the color coordinate value of the white compensation light may be: (0.2805, 0.2515), (0.2805, 0.2615), (0.2855, 0.2705), and (0.2855, 0.2805).

In this way, a color coordinate region of the plurality of rays of white compensation light emitted by the plurality of compensation light-emitting units 24 located within the same color block can have a relatively small area, so that the plurality of rays of white compensation light emitted by the plurality of compensation light-emitting units 24 in the display panel 1000 may have a relatively small chromaticity range, thereby improving the chromaticity uniformity of the display light emitted by the light-emitting substrate 100.

For example, the compensation light may be yellow compensation light. The coordinate point of the compensation light emitted by the compensation light-emitting unit 24 in the color coordinates may be located within a region enclosed by lines connecting a first color coordinate point (0.3275, 0.3577), a sixth color coordinate point (0.4500, 0.5500), and a seventh color coordinate point (0.5000, 0.5000).

By limiting the color coordinate point of the yellow compensation light in the color coordinates within a reasonable range, the luminance of the yellow compensation light can also be limited within a reasonable range, which may weaken the problem of low color purity and serious color deviation of the light-emitting substrate 100 caused by an excessively high amount of the yellow compensation light, so as to reasonably increase the emission luminance of the light-emitting substrate 100 on the basis of ensuring the color purity and the display effect of the light-emitting substrate 100. Furthermore, by limiting the color coordinate point of the yellow compensation light in the color coordinates within the reasonable range, the chromaticity range of the monochromatic light emitted by the light-emitting substrate 100 can also be reasonably limited, so that the chromaticity uniformity of the display light emitted by the light-emitting substrate 100 may be improved. For example, a wavelength of the yellow compensation light emitted by the compensation light-emitting unit 24 may be greater than or equal to 570 nm and less than or equal to 580 nm. For example, the wavelength of the yellow compensation light emitted by the compensation light-emitting unit 24 may be 570 nm, 571 nm, 572 nm, 573 nm, 574 nm, 575 nm, 576 nm, 577 nm, 578 nm, 579 nm, or 580 nm.

By limiting the wavelength of the yellow compensation light emitted by the compensation light-emitting unit 24 within the reasonable range, the wavelength range of the mixed light of the yellow compensation light and the light emitted by the light-emitting unit 20 can be made relatively small, so that the color purity of the mixed light of the yellow compensation light and the light emitted by the light-emitting unit 20 is high, thereby ensuring the color purity and display effect of the light-emitting substrate 100.

In some examples, the compensation light-emitting unit 24 may include a blue light-emitting unit and a color converter (not shown in the figure), in which the color converter may be located on a side of the blue light-emitting unit away from the base substrate 10, and blue light emitted by the blue light-emitting unit can be converted into the white compensation light or the yellow compensation light through the color converter.

For example, a material of the color converter may include fluorescent powder or quantum dot (QD) material. For example, the fluorescent powder may include yttrium aluminum garnet (YAG) fluorescent powder. The quantum dot material may include at least one of: a germanium quantum dot material, a cadmium sulfide quantum dot material, a cadmium selenide quantum dot material, a zinc selenide quantum dot material, a lead sulfide quantum dot material, a lead selenide quantum dot material, an indium phosphide quantum dot material, and an indium arsenide quantum dot material. With such a setting, the compensation light emitted by the compensation light-emitting unit 24 has good chromaticity uniformity and high color purity.

In some embodiments, a ratio of light-emitting areas of the compensation light-emitting units 24 to an area of the display region AA of the display panel 1000 may be greater than or equal to 0.1% and less than or equal to 5%. For example, the ratio of the light-emitting areas of the compensation light-emitting units 24 to the area of the display region AA of the display panel 1000 may be 0.1%, 0.3%, 0.5%, 0.8%, 1.0%, 1.5%, 2.0%, 2.5%, 3.0%, 3.5%, 4.0%, 4.5%, or 5%.

By reasonably limiting the ratio of the light-emitting areas of the compensation light-emitting units 24 to the area of the display region AA of the display panel 1000, the light amount of the compensation light emitted by the compensation light-emitting unit 24 can be limited within a reasonable range, so as to reasonably improve the emission luminance of the light-emitting substrate 100 and the chromaticity uniformity of the display light emitted by the light-emitting substrate 100, on the basis of ensuring the display effect of the light-emitting substrate 100.

To sum up, in the light-emitting substrate 100 and the display panel 1000 provided in the embodiments of the present disclosure, since the compensation light emitted by the compensation light-emitting unit 24 can be mixed with the light emitted by the light-emitting unit 20, the chromaticity range of the display light emitted by the light-emitting substrate 100 is reduced, thereby improving the uniformity of the luminance and chromaticity of the light-emitting substrate 100, and thereby meeting the light-emitting uniformity requirements of the light-emitting substrate 100. On the basis that the use of the compensation light-emitting unit 24 can satisfy the light-emitting uniformity requirements of the light-emitting substrate 100, compared to the foregoing schemes in which the light-emitting substrate 100 does not employ the compensation light-emitting unit 24, the coordinate points of the light emitted by any two light-emitting units 20 of the same color in the color coordinates in the same light-emitting substrate 100 herein have a large distance therebetween, making it possible to allow the light emitted by the plurality of light-emitting units 20 of the same color in the same light-emitting substrate 100 to have a large chromaticity range. Thus, it is possible to reduce the number of grades of the light-emitting units 20 divided according to the chromaticity at the stage of screening and grading, so that the utilization rate of the light-emitting units 20 may be improved. In this way, the difficulty of screening the light-emitting units 20 or the steps of screening the light-emitting units 20 may be reduced, thereby improving the manufacturing efficiency of the light-emitting substrate 100.

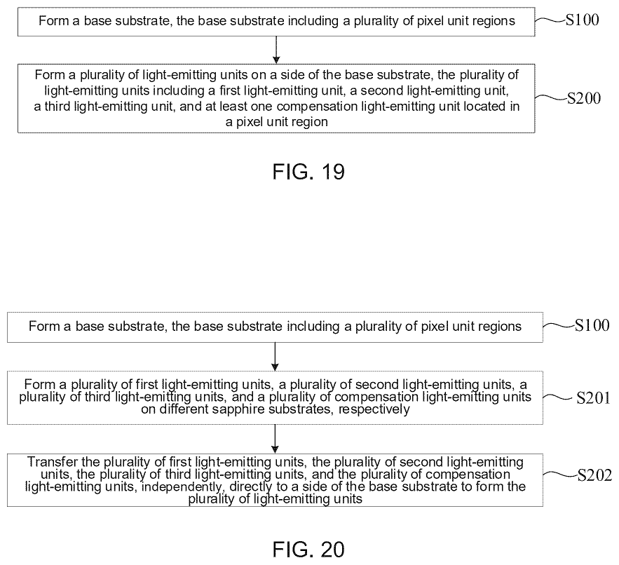

FIG. 19 and FIG. 20 are each a flowchart of a manufacturing method for a light-emitting substrate, in accordance with some embodiments.

Some embodiments of the present disclosure provide a manufacturing method for a light-emitting substrate 100. The manufacturing method for the light-emitting substrate 100 can be used to obtain the light-emitting substrate 100 as in any of the above embodiments. As shown in FIG. 19, the manufacturing method for the light-emitting substrate 100 may include a step S100 and a step S200.

In the step S100, a base substrate 10 is formed. The base substrate 10 includes a plurality of pixel unit regions.

As shown in FIG. 3 and FIG. 4, the base substrate 10 may include a plurality of pixel unit regions PU arranged with repetition. Each pixel unit region PU may include multiple sub-pixel regions and a non-light-emitting region FA located around each sub-pixel region. For example, each pixel unit region PU may include a first sub-pixel region P1, a second sub-pixel region P2, a third sub-pixel region P3, and at least one fourth sub-pixel region P4. The number of the fourth sub-pixel region(s) P4 in each pixel unit region PU may be one or more.

The specific structural features of the pixel unit region PU have been described in detail in the foregoing and will not be repeated here.

In some examples, the base substrate 10 may be a flexible base substrate 10. For example, a material of the flexible base substrate 10 may include an organic material. For example, the material of the flexible base substrate 10 may include any one of polyimide (PI), polycarbonate (PC), or polyvinyl chloride (PVC).

In some other examples, the base substrate 10 may be a rigid base substrate 10. For example, a material of the rigid base substrate 10 may include glass or polymethyl methacrylate (PMMA).

In some embodiments, the step S100 may further include forming a plurality of pixel circuits S on a side of the base substrate 10.

For example, a pixel unit region PU may be provided therein with a first pixel circuit S1, a second pixel circuit S2, and a third pixel circuit S3. For example, the first pixel circuit S1 is located in the first sub-pixel region P1, the second pixel circuit S2 is located in the second sub-pixel region P2, and the third pixel circuit S3 is located in the third sub-pixel region P3. As another example, a thin film transistor of at least one of the first pixel circuit S1, the second pixel circuit S2, and the third pixel circuit S3 may be located in the non-light-emitting region FA.

The structural features of the plurality of pixel circuits S have been described in detail in the foregoing and will not be repeated here.

In some examples, the step S100 may further include forming an insulating layer 30 on a side of the plurality of pixel circuits S away from the base substrate 10. The insulating layer 30 may be located on the pixel circuits S. The insulating layer 30 may have a planarized surface. The insulating layer 30 may be formed from an organic layer. For example, the insulating layer 30 may be made of an acrylic resin, an epoxy resin, an imide resin, or an ester resin. The insulating layer 30 may have through holes, and the through holes may expose the pixel circuits S to facilitate an electrical connection of the pixel circuits S to electrodes of the light-emitting units 20.

In the step S200, a plurality of light-emitting units 20 are formed on a side of the base substrate 20. The plurality of light-emitting units 20 include a plurality of first light-emitting units 21, a plurality of second light-emitting units 22, a plurality of third light-emitting units 23, and a plurality of compensation light-emitting units 24, in which a pixel unit region is provided therein with a first light-emitting unit 21, a second light-emitting unit 22, a third light-emitting unit 23, and at least one compensation light-emitting unit 24.

In some embodiments, a distance between a coordinate point of first color light emitted by one first light-emitting unit 21 in the color coordinates and a coordinate point of first color light emitted by another first light-emitting unit 21 in the color coordinates is greater than or equal to 0.035 (e.g., equal to 0.035, 0.038, 0.04, 0.042, 0.045, 0.05, 0.052, 0.055, 0.058, 0.06, or 0.065).

Since the compensation light emitted by the compensation light-emitting unit 24 can be mixed with the first color light, the chromaticity range of the display light emitted by the light-emitting substrate 100 is reduced, thereby improving the uniformity of the luminance and chromaticity of the light-emitting substrate 100, and thereby meeting the light-emitting uniformity requirements of the light-emitting substrate 100. In the embodiments of the present disclosure, on the basis that the use of the compensation light-emitting unit 24 can satisfy the light-emitting uniformity requirements of the light-emitting substrate 100, compared to the foregoing scheme in which the light-emitting substrate 100 does not employ the compensation light-emitting unit 24, the coordinate points of first color light emitted by any two first light-emitting units 21 in the color coordinates in the same light-emitting substrate 100 have a large distance therebetween, making it possible to allow the first color light emitted by the plurality of first light-emitting units 21 in the same light-emitting substrate 100 to have a large chromaticity range. Thus, it is possible to reduce the number of grades of the first light-emitting units 21 divided according to the chromaticity at the stage of screening and grading, so that the utilization rate of the first light-emitting units 21 may be improved. In this way, the difficulty of screening the first light-emitting units 21 or the steps of screening the first light-emitting units 21 may be reduced, thereby improving the manufacturing efficiency of the light-emitting substrate 100.

In some embodiments, a distance between a coordinate point of second color light emitted by one second light-emitting unit 22 in the color coordinates and a coordinate point of second color light emitted by another second light-emitting unit 22 in the color coordinates is greater than or equal to 0.023 (e.g., equal to 0.023, 0.025, 0.026, 0.028, 0.029, 0.03, 0.032, or 0.035).

Since the compensation light emitted by the compensation light-emitting unit 24 can be mixed with the second color light, the chromaticity range of the display light emitted by the light-emitting substrate 100 is reduced, thereby improving the uniformity of the luminance and chromaticity of the light-emitting substrate 100, and thereby meeting the light-emitting uniformity requirements of the light-emitting substrate 100. In the embodiments of the present disclosure, on the basis that the use of the compensation light-emitting unit 24 can satisfy the light-emitting uniformity requirements of the light-emitting substrate 100, compared to the foregoing scheme in which the light-emitting substrate 100 does not employ the compensation light-emitting unit 24, the coordinate points of second color light emitted by any two second light-emitting units 22 in the color coordinates in the same light-emitting substrate 100 have a large distance therebetween, making it possible to allow the second color light emitted by the plurality of second light-emitting units 22 in the same light-emitting substrate 100 to have a large chromaticity range. Thus, it is possible to reduce the number of grades of the second light-emitting units 22 divided according to the chromaticity at the stage of screening and grading, so that the utilization rate of the second light-emitting units 22 may be improved. In this way, the difficulty of screening the second light-emitting units 22 or the steps of screening the second light-emitting units 22 may be reduced, thereby improving the manufacturing efficiency of the light-emitting substrate 100.

In some embodiments, a distance between a coordinate point of third color light emitted by one third light-emitting unit 23 in the color coordinates and a coordinate point of third color light emitted by another third light-emitting unit 23 in the color coordinates is greater than or equal to 0.005 (e.g., equal to 0.005, 0.006, 0.007, 0.008, 0.009, 0.010, 0.012, or 0.015).

Since the compensation light emitted by the compensation light-emitting unit 24 can be mixed with the third color light, the chromaticity range of the display light emitted by the light-emitting substrate 100 is reduced, thereby improving the uniformity of the luminance and chromaticity of the light-emitting substrate 100, and thereby meeting the light-emitting uniformity requirements of the light-emitting substrate 100. In the embodiments of the present disclosure, on the basis that the use of the compensation light-emitting unit 24 can satisfy the light-emitting uniformity requirements of the light-emitting substrate 100, compared to the foregoing scheme in which the light-emitting substrate 100 does not employ the compensation light-emitting unit 24, the coordinate points of third color light emitted by any two third light-emitting units 23 in the color coordinates in the same light-emitting substrate 100 have a large distance therebetween, making it possible to allow the third color light emitted by the plurality of third light-emitting units 23 in the same light-emitting substrate 100 to have a large chromaticity range. Thus, it is possible to reduce the number of grades of the third light-emitting units 23 divided according to the chromaticity at the stage of screening and grading, so that the utilization rate of the third light-emitting units 23 may be improved. In this way, the difficulty of screening the third light-emitting units 23 or the steps of screening the third light-emitting units 23 may be reduced, thereby improving the manufacturing efficiency of the light-emitting substrate 100.

In some embodiments, as shown in FIG. 20, the step S200 may include a step S201 and a step S202.

In the step S201, a plurality of first light-emitting units 21, a plurality of second light-emitting units 22, a plurality of third light-emitting units 23, and a plurality of compensation light-emitting units 24 are formed on different sapphire substrates, respectively.

In the step S202, the plurality of first light-emitting units 21, the plurality of second light-emitting units 22, the plurality of third light-emitting units 23, and the plurality of compensation light-emitting units 24, independently, are directly transferred to a side of the base substrate to form the plurality of light-emitting units.

Since the light-emitting substrate 100 in the embodiments of the present disclosure can allow the light emitted by the light-emitting unit 20 to have a large chromaticity range, which can reduce the number of grades of the light-emitting units 20 divided according to the chromaticity at the stage of screening and grading. In this way, the steps of screening the light-emitting units 20 may be omitted, and the mass transfer may be made directly to the light-emitting units 20, which may simplify the manufacturing process of the light-emitting substrate 100, and thus may improve the utilization rate of the light-emitting units 20 and the manufacturing efficiency of the light-emitting substrate 100.

In some examples, the step S201 may include: forming a plurality of first light-emitting units 21 connected to each other by epitaxial growth on a side of a sapphire substrate, and thereafter, forming the plurality of first light-emitting units 21 independent of each other by laser cutting.

The step S202 may include transferring the plurality of first light-emitting units 21 independent of each other to a side of the insulating layer 30 away from the base substrate 10 directly.

For the plurality of second light-emitting units 22, the plurality of third light-emitting units 23, and the plurality of compensation light-emitting units 24 formed in the step S200, each type of light-emitting units may be formed by referring to the method of forming the plurality of first light-emitting units 21 described above, and will not be repeated here. The plurality of first light-emitting units 21, the plurality of second light-emitting units 22, the plurality of third light-emitting units 23, and the plurality of compensation light-emitting units 24 form the plurality of light-emitting units 20.

The specific structural features of the light-emitting units 20 have been described in detail in the foregoing and will not be repeated here.

To sum up, in the light-emitting substrate 100 obtained by the manufacturing method for the light-emitting substrate 100 provided in the embodiments of the present disclosure, since the compensation light emitted by the compensation light-emitting unit 24 can be mixed with the light emitted by the light-emitting unit 20, the chromaticity range of the display light emitted by the light-emitting substrate 100 is reduced, thereby improving the uniformity of the luminance and chromaticity of the light-emitting substrate 100, and thereby meeting the light-emitting uniformity requirements of the light-emitting substrate 100. On the basis that the use of the compensation light-emitting unit 24 can satisfy the light-emitting uniformity requirements of the light-emitting substrate 100, compared to the foregoing schemes in which the light-emitting substrate 100 does not employ the compensation light-emitting unit 24, the coordinate points of the light emitted by any two light-emitting units 20 of the same color in the color coordinates in the same light-emitting substrate 100 herein have a large distance therebetween, making it possible to allow the light emitted by the plurality of light-emitting units 20 of the same color in the same light-emitting substrate 100 to have a large chromaticity range. Thus, it is possible to reduce the number of grades of the light-emitting units 20 divided according to the chromaticity at the stage of screening and grading, so that the utilization rate of the light-emitting units 20 may be improved. In this way, the difficulty of screening the light-emitting units 20 or the steps of screening the light-emitting units 20 may be reduced, thereby improving the manufacturing efficiency of the light-emitting substrate 100.

Some embodiments of the present disclosure provide a driving method for a light-emitting substrate 100. The driving method for the light-emitting substrate 100 may include adjusting a luminance of at least one of the first light-emitting unit 21, the second light-emitting unit 22, the third light-emitting unit 23, and the compensation light-emitting unit 24 separately, by adjusting a driving current or a duty cycle of a driving voltage.

In some examples, in a case where the light-emitting units 20 employ an active driving method, the driving method for the light-emitting substrate 100 may include: adjusting a luminance of a first light-emitting unit 21 by adjusting a driving current on a first electrode AE or a driving current on a second electrode CE of the first light-emitting unit 21; and/or adjusting a luminance of compensation light emitted by a compensation light-emitting unit 24 corresponding to a first light-emitting unit 21 by adjusting a driving current on a first electrode AE or a driving current on a second electrode CE of the compensation light-emitting unit 24 corresponding to the first light-emitting unit 21.

In some other examples, in a case where the light-emitting units 20 employ a passive driving method, the driving method for the light-emitting substrate 100 may include: adjusting a luminance of a first light-emitting unit 21 by adjusting a duty cycle of a driving voltage on a first electrode AE or a duty cycle of a driving voltage on a second electrode CE of the first light-emitting unit 21; and/or adjusting a luminance of compensation light emitted by a compensation light-emitting unit 24 corresponding to a first light-emitting unit 21 by adjusting a duty cycle of a driving voltage on a first electrode AE or a duty cycle of a driving voltage on a second electrode CE of the compensation light-emitting unit 24 corresponding to the first light-emitting unit 21.

The method of adjusting a luminance of each of the second light-emitting unit 22 and the third light-emitting unit 23 with a corresponding compensation light-emitting unit 24 can be referred to the method of adjusting the luminance of the first light-emitting unit 21 and the corresponding compensation light-emitting unit 24 described above, and will not be repeated here.

In this way, a ratio between the luminance of the compensation light emitted by the compensation light-emitting unit 24 and the luminance of the light emitted by the corresponding light-emitting unit 20 can be adjusted, so that the luminance of the display light emitted by the display panel 1000 may be increased. On the basis of improving the luminance of the display light emitted by the display panel 1000, the uniformity of luminance and chromatic of the light-emitting substrate 100 may be improved as the compensation light emitted by the compensation light-emitting unit 24 can be mixed with the light emitted by the light-emitting unit 20, thereby reducing the range of the chromaticity of the display light emitted by the light-emitting substrate 100. Moreover, the display effect of the display panel 1000 may be ensured, as well as the color gamut coverage area of the display light emitted by the display panel 1000 may be ensured to be relatively large.

In some embodiments, a distance between a coordinate point of first color light emitted by one first light-emitting unit 21 in the color coordinates and a coordinate point of first color light emitted by another first light-emitting unit 21 in the color coordinates is greater than or equal to 0.035 (e.g., equal to 0.035, 0.038, 0.04, 0.042, 0.045, 0.05, 0.052, 0.055, 0.058, 0.06, or 0.065).

Since the compensation light emitted by the compensation light-emitting unit 24 can be mixed with the first color light, the chromaticity range of the display light emitted by the light-emitting substrate 100 is reduced, thereby improving the uniformity of the luminance and chromaticity of the light-emitting substrate 100, and thereby meeting the light-emitting uniformity requirements of the light-emitting substrate 100. In the embodiments of the present disclosure, on the basis that the use of the compensation light-emitting unit 24 can satisfy the light-emitting uniformity requirements of the light-emitting substrate 100, compared to the foregoing scheme in which the light-emitting substrate 100 does not employ the compensation light-emitting unit 24, the coordinate points of first color light emitted by any two first light-emitting units 21 in the color coordinates in the same light-emitting substrate 100 have a large distance therebetween, making it possible to allow the first color light emitted by the plurality of first light-emitting units 21 in the same light-emitting substrate 100 to have a large chromaticity range. Thus, it is possible to reduce the number of grades of the first light-emitting units 21 divided according to the chromaticity at the stage of screening and grading, so that the utilization rate of the first light-emitting units 21 may be improved. In this way, the difficulty of screening the first light-emitting units 21 or the steps of screening the first light-emitting units 21 may be reduced, thereby improving the manufacturing efficiency of the light-emitting substrate 100.

In some embodiments, a distance between a coordinate point of second color light emitted by one second light-emitting unit 22 in the color coordinates and a coordinate point of second color light emitted by another second light-emitting unit 22 in the color coordinates is greater than or equal to 0.023 (e.g., equal to 0.023, 0.025, 0.026, 0.028, 0.029, 0.03, 0.032, or 0.035).

Since the compensation light emitted by the compensation light-emitting unit 24 can be mixed with the second color light, the chromaticity range of the display light emitted by the light-emitting substrate 100 is reduced, thereby improving the uniformity of the luminance and chromaticity of the light-emitting substrate 100, and thereby meeting the light-emitting uniformity requirements of the light-emitting substrate 100. In the embodiments of the present disclosure, on the basis that the use of the compensation light-emitting unit 24 can satisfy the light-emitting uniformity requirements of the light-emitting substrate 100, compared to the foregoing scheme in which the light-emitting substrate 100 does not employ the compensation light-emitting unit 24, the coordinate points of second color light emitted by any two second light-emitting units 22 in the color coordinates in the same light-emitting substrate 100 have a large distance therebetween, making it possible to allow the second color light emitted by the plurality of second light-emitting units 22 in the same light-emitting substrate 100 to have a large chromaticity range. Thus, it is possible to reduce the number of grades of the second light-emitting units 22 divided according to the chromaticity at the stage of screening and grading, so that the utilization rate of the second light-emitting units 22 may be improved. In this way, the difficulty of screening the second light-emitting units 22 or the steps of screening the second light-emitting units 22 may be reduced, thereby improving the manufacturing efficiency of the light-emitting substrate 100.

In some embodiments, a distance between a coordinate point of third color light emitted by one third light-emitting unit 23 in the color coordinates and a coordinate point of third color light emitted by another third light-emitting unit 23 in the color coordinates is greater than or equal to 0.005 (e.g., equal to 0.005, 0.006, 0.007, 0.008, 0.009, 0.010, 0.012, or 0.015).

Since the compensation light emitted by the compensation light-emitting unit 24 can be mixed with the third color light, the chromaticity range of the display light emitted by the light-emitting substrate 100 is reduced, thereby improving the uniformity of the luminance and chromaticity of the light-emitting substrate 100, and thereby meeting the light-emitting uniformity requirements of the light-emitting substrate 100. In the embodiments of the present disclosure, on the basis that the use of the compensation light-emitting unit 24 can satisfy the light-emitting uniformity requirements of the light-emitting substrate 100, compared to the foregoing scheme in which the light-emitting substrate 100 does not employ the compensation light-emitting unit 24, the coordinate points of third color light emitted by any two third light-emitting units 23 in the color coordinates in the same light-emitting substrate 100 have a large distance therebetween, making it possible to allow the third color light emitted by the plurality of third light-emitting units 23 in the same light-emitting substrate 100 to have a large chromaticity range. Thus, it is possible to reduce the number of grades of the third light-emitting units 23 divided according to the chromaticity at the stage of screening and grading, so that the utilization rate of the third light-emitting units 23 may be improved. In this way, the difficulty of screening the third light-emitting units 23 or the steps of screening the third light-emitting units 23 may be reduced, thereby improving the manufacturing efficiency of the light-emitting substrate 100.

To sum up, in the driving method for the light-emitting substrate 100 provided in the embodiments of the present disclosure, the ratio between the luminance of the light emitted by the light-emitting unit 20 and the luminance of the compensation light emitted by the corresponding compensation light-emitting unit 24 can be adjusted by adjusting the driving current of the light-emitting unit 20 or adjusting the duty cycle of the driving voltage of the light-emitting unit 20, thereby increasing the luminance of the display light emitted by the display panel 1000, ensuring the display effect of the display panel 1000, and ensuring the color gamut coverage area of the display light emitted by the display panel 1000 to be relatively large. Furthermore, On the basis that the use of the compensation light-emitting unit 24 can satisfy the light-emitting uniformity requirements of the light-emitting substrate 100, compared to the foregoing schemes in which the light-emitting substrate 100 does not employ the compensation light-emitting unit 24, the coordinate points of the light emitted by any two light-emitting units 20 of the same color in the color coordinates in the same light-emitting substrate 100 herein have a large distance therebetween, making it possible to allow the light emitted by the plurality of light-emitting units 20 of the same color in the same light-emitting substrate 100 to have a large chromaticity range. Thus, it is possible to reduce the number of grades of the light-emitting units 20 divided according to the chromaticity at the stage of screening and grading, so that the utilization rate of the light-emitting units 20 may be improved. In this way, the difficulty of screening the light-emitting units 20 or the steps of screening the light-emitting units 20 may be reduced, thereby improving the manufacturing efficiency of the light-emitting substrate 100.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A light-emitting substrate, comprising:
a base substrate, including a plurality of pixel unit regions; and
a plurality of light-emitting units, located on a side of the base substrate and including a plurality of first light-emitting units, a plurality of second light-emitting units, a plurality of third light-emitting units, and a plurality of compensation light-emitting units, wherein each pixel unit region is provided therein with a first light-emitting unit in the first light-emitting units, a second light-emitting unit in the second light-emitting units, a third light-emitting unit in the third light-emitting units, and at least one compensation light-emitting unit in the compensation, light-emitting units, wherein
a distance between a coordinate point of first color light emitted by one of the first light-emitting units in color coordinates and a coordinate point of first color light emitted by another of the first light-emitting units in the color coordinates is greater than or equal to 0.035; and/or
a distance between a coordinate point of second color light emitted by one of the second light-emitting units in the color coordinates and a coordinate point of second color light emitted by another of the second light-emitting units in the color coordinates is greater than or equal to 0.023; and/or
a distance between a coordinate point of third color light emitted by one of the third light-emitting units in the color coordinates and a coordinate point of third color light emitted by another of the third light-emitting units in the color coordinates is greater than or equal to 0.005.

2. The light-emitting substrate according to claim 1, wherein a distance between a coordinate point of first color light emitted by one of the first light-emitting units in color coordinates and a coordinate point of first color light emitted by another of the first light-emitting units in the color coordinates is greater than or equal to 0.042; and/or
a distance between a coordinate point of second color light emitted by one of the second light-emitting units in the color coordinates and a coordinate point of second color light emitted by another of the second light-emitting units in the color coordinates is greater than or equal to 0.026; and/or
a distance between a coordinate point of third color light emitted by one of the third light-emitting units in the color coordinates and a coordinate point of third color light emitted by another of the third light-emitting units in the color coordinates is greater than or equal to 0.007.

3. The light-emitting substrate according to claim 1, wherein an area of a first MacAdam ellipse region corresponding to third color light emitted by the third light-emitting unit is less than an area of a second MacAdam ellipse region corresponding to mixed light of the third color light emitted by the third light-emitting unit and compensation light emitted by a compensation light-emitting unit.

4. The light-emitting substrate according to claim 3, wherein a range value of the first MacAdam ellipse region on a first coordinate axis in the color coordinates is less than a range value of the second MacAdam ellipse region on the first coordinate axis; and/or
a range value of the first MacAdam ellipse region on a second coordinate axis in the color coordinates is less than a range value of the second MacAdam ellipse region on the second coordinate axis.

5. The light-emitting substrate according to claim 3, wherein a ratio of a range value of the third color light on a first coordinate axis in the color coordinates to a range value of the first MacAdam ellipse region on the first coordinate axis is M1, and a ratio of a range value of the mixed light of the third color light and the compensation light on the first coordinate axis in the color coordinates to a range value of the second MacAdam ellipse region on the first coordinate axis is N1, M1 being greater than N1; and/or
a ratio of a range value of the third color light on a second coordinate axis in the color coordinates to a range value of the first MacAdam ellipse region on the second coordinate axis is M2, and a ratio of a range value of the mixed light of the third color light and the compensation light on the second coordinate axis in the color coordinates to a range value of the second MacAdam ellipse region on the second coordinate axis is N2, M2 being greater than N2.

6. The light-emitting substrate according to claim 1, wherein a pixel unit region in the pixel unit regions is provided therein with one first light-emitting unit, one second light-emitting unit, one third light-emitting unit, and one compensation light-emitting unit;
an attenuation rate of an emission luminance of the first light-emitting unit corresponding to a single lighting duration is greater than an attenuation rate of an emission luminance of the second light-emitting unit corresponding to the single lighting duration, and the attenuation rate of the emission luminance of the first light-emitting unit corresponding to the single lighting duration is greater than an attenuation rate of an emission luminance of the third light-emitting unit corresponding to the single lighting duration; and
the compensation light-emitting unit is located adjacent to the first light-emitting unit.

7. The light-emitting substrate according to claim 1, wherein a pixel unit region in the pixel unit regions is provided therein with one first light-emitting unit, one second light-emitting unit, one third light-emitting unit, and two compensation light-emitting units;
an emission luminance of the first light-emitting unit is less than an emission luminance of the second light-emitting unit, and the emission luminance of the second light-emitting unit is greater than an emission luminance of the third light-emitting unit; and
one of the two compensation light-emitting units is located adjacent to the first light-emitting unit, and the other of the two compensation light-emitting units is located adjacent to the third light-emitting unit.

8. The light-emitting substrate according to claim 1, wherein a pixel unit region in the pixel unit regions is provided therein with one first light-emitting unit, one second light-emitting unit, one third light-emitting unit, and three compensation light-emitting units;
the three compensation light-emitting units include a first compensation light-emitting unit, a second compensation light-emitting unit, and a third compensation light-emitting unit; and
along a direction parallel to the base substrate, the first compensation light-emitting unit is located adjacent to the first light-emitting unit, the second compensation light-emitting unit is located adjacent to the second light-emitting unit, and the third compensation light-emitting unit is located adjacent to the third light-emitting unit.

9. The light-emitting substrate according to claim 8, wherein a ratio of an emission luminance of the first compensation light-emitting unit to an emission luminance of the first light-emitting unit, a ratio of an emission luminance of the second compensation light-emitting unit to an emission luminance of the second light-emitting unit, and a ratio of an emission luminance of the third compensation light-emitting unit to an emission luminance of the third light-emitting unit are different from each other.

10. The light-emitting substrate according to claim 8, wherein an attenuation rate of an emission luminance of the first light-emitting unit corresponding to a single lighting duration is greater than an attenuation rate of an emission luminance of the second light-emitting unit corresponding to the single lighting duration; a difference between a ratio of an emission luminance of the first compensation light-emitting unit to an emission luminance of the first light-emitting unit at a first moment and a ratio of an emission luminance of the first compensation light-emitting unit to an emission luminance of the first light-emitting unit at a second moment is a first ratio difference; a difference between a ratio of an emission luminance of the second compensation light-emitting unit to an emission luminance of the second light-emitting unit at the first moment and a ratio of an emission luminance of the second compensation light-emitting unit to an emission luminance of the second light-emitting unit at the second moment is a second ratio difference; and the first ratio difference is greater than the second ratio difference; and/or
an attenuation rate of an emission luminance of the second light-emitting unit corresponding to a single lighting duration is greater than an attenuation rate of an emission luminance of the third light-emitting unit corresponding to the single lighting duration; a difference between a ratio of an emission luminance of the second compensation light-emitting unit to an emission luminance of the second light-emitting unit at the first moment and a ratio of an emission luminance of the second compensation light-emitting unit to an emission luminance of the second light-emitting unit at the second moment is a third ratio difference; a difference between a ratio of an emission luminance of the third compensation light-emitting unit to an emission luminance of the third light-emitting unit at the first moment and a ratio of an emission luminance of the third compensation light-emitting unit to an emission luminance of the third light-emitting unit at the second moment is a fourth ratio difference; and the third ratio difference is greater than the fourth ratio difference;
wherein the first moment is a moment between a lighting moment and the second moment.

11. The light-emitting substrate according to claim 1, wherein in different pixel unit regions, a ratio of an emission luminance of a compensation light-emitting unit to an emission luminance of the first light-emitting unit is substantially the same; and/or
in different pixel unit regions, a ratio of an emission luminance of a compensation light-emitting unit to an emission luminance of the second light-emitting unit is substantially the same; and/or
in different pixel unit regions, a ratio of an emission luminance of a compensation light-emitting unit to an emission luminance of the third light-emitting unit is substantially the same.

12. The light-emitting substrate according to claim 1, wherein a ratio of an emission luminance of a compensation light-emitting unit to an emission luminance of the first light-emitting unit is greater than or equal to 10% and less than or equal to 50%; and/or
a ratio of an emission luminance of a compensation light-emitting unit to an emission luminance of the second light-emitting unit is greater than or equal to 10% and less than or equal to 50%; and/or
a ratio of an emission luminance of a compensation light-emitting unit to an emission luminance of the third light-emitting unit is greater than or equal to 10% and less than or equal to 50%.

13. The light-emitting substrate according to claim 1, wherein a light-emitting area of a compensation light-emitting unit is substantially equal to a light-emitting area of the first light-emitting unit; and/or
a light-emitting area of a compensation light-emitting unit is substantially equal to a light-emitting area of the second light-emitting unit; and/or
a light-emitting area of a compensation light-emitting unit is substantially equal to a light-emitting area of the third light-emitting unit.

14. The light-emitting substrate according to claim 1, wherein a coordinate point of compensation light emitted by the at least one compensation light-emitting unit in the color coordinates is located within a region enclosed by lines connecting a first color coordinate point (0.3275, 0.3577), a second color coordinate point (0.3750, 0.6250), and a third color coordinate point (0.6000, 0.4000).

15. The light-emitting substrate according to claim 1, wherein a coordinate point of compensation light emitted by a compensation light-emitting unit in the compensation light-emitting units in the color coordinates is located within a region enclosed by lines connecting a first color coordinate point (0.3275, 0.3577), a fourth color coordinate point (0.2800, 0.2500), and a fifth color coordinate point (0.2600, 0.2600); and/or
a coordinate point of compensation light emitted by another compensation light-emitting unit in the compensation light-emitting units in the color coordinates is located within a region enclosed by lines connecting a first color coordinate point (0.3275, 0.3577), a sixth color coordinate point (0.4500, 0.5500), and a seventh color coordinate point (0.5000, 0.5000).

16. A manufacturing method for a light-emitting substrate, the manufacturing method comprising:
forming a base substrate, the base substrate including a plurality of pixel unit regions; and
forming a plurality of light-emitting units on a side of the base substrate, the plurality of light-emitting units including a plurality of first light-emitting units, a plurality of second light-emitting units, a plurality of third light-emitting units, and a plurality of compensation light-emitting units, wherein each pixel unit region is provided therein with a first light-emitting unit in the first light-emitting units, a second light-emitting unit in the second light-emitting units, a third light-emitting unit in the third light-emitting units, and at least one compensation light-emitting unit in the compensation light-emitting units, wherein a distance between a coordinate point of first color light emitted by one of the first light-emitting units in color coordinates and a coordinate point of first color light emitted by another of the first light-emitting units in the color coordinates is greater than or equal to 0.035; and/or a distance between a coordinate point of second color light emitted by one of the second light-emitting units in the color coordinates and a coordinate point of second color light emitted by another of the second light-emitting units in the color coordinates is greater than or equal to 0.023; and/or a distance between a coordinate point of third color light emitted by one of the third light-emitting units in the color coordinates and a coordinate point of third color light emitted by another of the third light-emitting units in the color coordinates is greater than or equal to 0.005.

17. The manufacturing method for the light-emitting substrate according to claim 16, wherein forming the plurality of light-emitting units on the side of the base substrate includes:
forming the plurality of first light-emitting units, the plurality of second light-emitting units, the plurality of third light-emitting units, and the plurality of compensation light-emitting units on different sapphire substrates, respectively; and
transferring the plurality of first light-emitting units, the plurality of second light-emitting units, the plurality of third light-emitting units, and the plurality of compensation light-emitting units, independently, directly to the side of the base substrate to form the plurality of light-emitting units.

18. A driving method for a light-emitting substrate, the light-light-emitting substrate including a plurality of first light-emitting units, a plurality of second light-emitting units, a plurality of third light-emitting units, and a plurality of compensation light-emitting units, wherein each pixel unit region is provided therein with a first light-emitting unit in the first light-emitting units, a second light-emitting unit in the second light-emitting units, a third light-emitting unit in the third light-emitting units, and a compensation light-emitting unit in the compensation light-emitting units; the driving method comprising:
adjusting a luminance of at least one of the first light-emitting unit, the second light-emitting unit, the third light-emitting unit, and the compensation light-emitting unit separately, by adjusting a driving current or a duty cycle of a driving voltage, to enable: a distance between a coordinate point of first color light emitted by one of the first light-emitting units in color coordinates and a coordinate point of first color light emitted by another of the first light-emitting units in the color coordinates to be greater than or equal to 0.035; and/or a distance between a coordinate point of second color light emitted by one of the second light-emitting units in the color coordinates and a coordinate point of second color light emitted by another of the second light-emitting units in the color coordinates to be greater than or equal to 0.023; and/or a distance between a coordinate point of third color light emitted by one of the third light-emitting units in the color coordinates and a coordinate point of third color light emitted by another of the third light-emitting units in the color coordinates to be greater than or equal to 0.005

19. A display panel, comprising:
the light-emitting substrate according to claim 1.

20. The display panel according to claim 19, wherein the display panel comprises a display region, wherein a ratio of light-emitting areas of the plurality of compensation light-emitting units to an area of the display region is greater than or equal to 0.1% and less than or equal to 5%.
